(19) United States
(12) Patent Application Publication
(10) Pub. No.: US 2014/0225611 A1
(43) Pub. Date: Aug. 14, 2014

(54) DEVICE FOR MRI IMAGING THE NEAR SURFACE OF TISSUE SPECIMENS

(71) Applicant: ASPECT IMAGING LTD., Shoham (IL)

(72) Inventor: Uri RAPOPORT, Moshav Ben Shemen (IL)

(73) Assignee: ASPECT IMAGING LTD., Shoham (IL)

(21) Appl. No.: 14/178,882

(22) Filed: Feb. 12, 2014

(30) Foreign Application Priority Data
Feb. 12, 2013 (DE) 20 2013 100 627.0

(51) Int. Cl. G01R 33/30; G01R 33/56

(52) U.S. Cl. CPC G01R 33/30; G01R 33/5601
USPC 324/309; 324/322; 324/321

(57) ABSTRACT

A system for MRI imaging the near surface of tissue specimens wherein the volume of interest of the MRI is held substantially within the surface-proximate tissue of the specimen by means of some combination of maneuvering the specimen, maneuvering the MRI RF magnetic field magnet, maneuvering the MRI RF receiver coil, maneuvering the static field magnets, and reshaping the tissue.

### FIELD AND BACKGROUND OF THE INVENTION

It is a long felt need to provide a means of determining the cancer status of near-surface regions of excised tissue in near real time, so that, if necessary, further excision can be done without the need for multiple operations. The present invention thus pertains to a new system for imaging the near surface of excised tissue specimens.

### SUMMARY

It is an object of the present invention to disclose a system for determining the cancer status of near-surface regions of excised tissue in near real time, so that, if necessary, further excision can be done without the need for multiple operations. The present invention thus pertains to a new system for imaging the near surface of excised tissue specimens.

It is another object of the present invention to disclose a system for MRI imaging the near surface of at least one tissue specimen comprising:
a. an MRI comprising at least two static magnetic field magnets, at least one RF magnetic field magnet and at least one RF receiver coil, said MRI adapted to image only portions of said tissue specimen proximate to the surface of said tissue specimen; and
b. a maneuvering controller comprising a processing system, said processing system configured to control maneuvering of at least one member of a group consisting of said static magnetic field magnets, said RF magnetic field magnets, said RF receiver coils, at least one said tissue specimen and any combination thereof such that the volume of interest of said MRI is substantially within said surface-proximate tissue;
   wherein said manuevering controller is configured to enable sequential imaging of substantially all of said surface-proximate tissue.

It is another object of the present invention to disclose a system for MRI imaging the near surface of at least one tissue specimen comprising:
a. an MRI comprising at least two static magnetic field magnets, at least one RF magnetic field magnet and at least one RF receiver coil, said MRI adapted to image only portions of said tissue specimen proximate to the surface of said tissue specimen; and
b. a maneuvering controller comprising a processing system, said processing system configured to enable sequential imaging of substantially all of said surface-proximate tissue by controlling maneuvering of at least one member of a group consisting of said static magnetic field magnets, said RF magnetic field magnets, said RF receiver coils, at least one said tissue specimen and any combination thereof such that the volume of interest of said MRI is substantially within said surface-proximate tissue;
wherein said volume of interest of said MRI is held substantially within said surface-proximate tissue by means of at least one of the following:
(a) said processing system is configured to enable circumnavigation of said tissue specimen by at least one of a group consisting of said static magnetic field magnets, said RF magnetic field magnets, said circumnavigation being around a vertical axis through approximately the center of said tissue specimen, said circumnavigation adapted to retain the volume of interest of said MRI within said surface-proximate tissue;
(b) at least one member of a group consisting of said RF magnetic field magnets, said RF receiver coils and any combination thereof is disposed about said tissue specimen in a horizontal planar configuration adapted to at least partially surround said tissue specimen, one direction of said maneuvering being parallel to a vertical axis through approximately the center of said tissue specimen;
(c) said MRI comprises at least one packed array of MRI/NMR devices of substantially no fringing magnetic fields, adapted to analyze at least one of adjacent tissue specimens and adjacent portions of said at least one tissue specimen and further comprising a pneumatic delivery system adapted to deliver said at least one of adjacent tissue specimens and adjacent portions of said at least one tissue specimen to stages of said packed may, wherein said adjacent MRI/NMR devices differ in at least one of a group consisting of resolution, contrast and signal-to-noise ratio;
(d) said processing system is configured to maneuver said specimen in at least two directions; and
(e) any combination thereof,

It is another object of the present invention to disclose the system, wherein said system is adapted to acquire time-varying MRI images.

It is another object of the present invention to disclose the system, wherein at least one of the following is held true:
a. said processing system is adapted to enable circumnavigation of said tissue specimen by at least one of a group consisting of said static magnetic field magnets, said RF magnetic field magnets, said circumnavigation being around a vertical axis through approximately the center of said tissue specimen, said circumnavigation adapted to retain the volume of interest of said MRI within said surface-proximate tissue;
b. at least one of a group consisting of said RF magnetic field magnets, said RF receiver coils and any combination thereof is disposed about said tissue specimen in a horizontal planar configuration adapted to at least partially surround said tissue specimen, one direction of said maneuvering being parallel to a vertical axis through approximately the center of said tissue specimen;
c. said MRI comprises at least one packed array of MRI/NMR devices of substantially no fringing magnetic fields, adapted to analyze at least one of adjacent tissue specimens and adjacent portions of said at least one tissue specimen and further comprising a pneumatic delivery system adapted to deliver said at least one of adjacent tissue specimens and adjacent portions of said at least one tissue specimen to stages of said packed array, wherein said adjacent MRI/NMR devices differ in at least one of a group consisting of resolution, contrast and signal-to-noise ratio;
d. said system is adapted to acquire time-varying MRI images;
e. any combination thereof.

It is another object of the present invention to disclose the system, wherein at least one of the following is held true:
a. said static magnetic field magnets are low-field magnets adapted to create high contrast images such that images of cancerous tissue appear to be a different intensity from images of non-cancerous tissue;
b. said system additionally comprises a contrast enhancer adapted to increase over untreated tissue at least one of a group selected from (i) the signal from at least some portion of said surface-proximate tissue of said tissue specimen, and (ii) the difference between at least one response to MRI of cancerous tissue and the same at least one response to MRI of normal tissue;
said contrast enhancer selected from a group consisting of a hyperpolarizing agent, a contrast agent and any combination thereof;
said contrast enhancer employed in a manner selected from a group consisting of (i) said contrast enhancer comprises a pretreatment fluid, said tissue specimen immersible in said pretreatment fluid; (ii) said contrast enhancer is adapted to be applied to said surface-proximate tissue and any combination thereof;
said tissue treated with said contrast enhancer in a manner selected from a group consisting of: in-vivo, such that said tissue specimen is treated with said contrast enhancer before excision, ex-vivo, such that said tissue specimen is treated with said contrast enhancer after excision and any combination thereof;
said in-vivo treatment selected from a group consisting of: at least one hyperpolarizing agent adapted to be introduced into said body; at least one hyperpolarization agent adapted to contact said body, said hyperpolarization agent adapted to induce hyperpolarization of at least a portion of said body via said contact; at least one hyperpolarization agent adapted to be placed in proximity to but not in contact with said body, said hyperpolarization agent adapted to induce hyperpolarization of at least a portion of said body via said proximity; at least one contrast agent adapted to be introduced into said body and any combination thereof;
said ex-vivo treatment selected from a group consisting of: at least one hyperpolarizing agent adapted to be introduced into said tissue specimen; at least one hyperpolarization agent adapted to contact said tissue specimen, said hyperpolarization agent adapted to induce hyperpolarization of at least a portion of said tissue specimen via said contact; at least one hyperpolarization agent adapted to be placed in proximity to but not in contact with said tissue specimen, said hyperpolarization agents adapted to induce hyperpolarization of at least a portion of said tissue specimen via said proximity; at least one contrast agent adapted to contact said tissue specimen, and any combination thereof;
contact between said excised tissue and contrast enhancement material is selected from a group consisting of: immersion of said excised tissue specimen in contrast enhancement fluid, injection of contrast enhancement material into said tissue specimen, coating of contrast enhancement material on said excised tissue specimen, and placement of contrast enhancement material in close proximity to said tissue specimen.

It is another object of the present invention to disclose the system, wherein said hyperpolarizing agent is selected from a group consisting of water, other hyperpolarizable liquids, ¹²⁹Xe, ³He, anesthetic gas, oxygen, an injectable solution containing ¹³C and any combination thereof.

It is another object of the present invention to disclose the system, The system of claim 3, wherein said contrast agent is selected from at least one of a group consisting of functional paramagnetic particles (FPP), superparamagnetic iron platinum particles, Gadolinium(III)-containing MRI contrast agents, iron oxide contrast agents, Mn-based nanoparticles, manganese ions (Mn²⁺), SPIO, barium sulfate, air, clay, Perflubron, peptides linked to high payload MRI contrast agents, antibodies linked to high payload MRI contrast agents, small ligands linked to high payload MRI contrast agents, small protein domains linked to high payload MRI contrast agents, peptides linked to MRI contrast agents with high relaxivities, antibodies linked to MRI contrast agents with high relaxivities, small ligands linked to MRI contrast agents with high relaxivities, small protein domains linked to MRI contrast agents with high relaxivities, ³He, ⁷Li, ¹³C, ¹⁹F, ¹⁷O, ²³Na, ³¹P and ¹²⁹Xe.

It is another object of the present invention to disclose the system, additionally comprising containment means for said tissue specimen;
said containment means selected from a group consisting of: a canister of predetermined shape to contain said tissue specimen, said canister adapted to induce said tissue specimen into said predetermined shape; a canister adapted to contain said tissue specimen while retaining substantially unaffected said tissue specimen's shape, said canister either containing only gas or at least partially filled with a liquid, said liquid at least partially supporting said tissue specimen; a cradle and mortar adapted to contain said tissue specimen, said cradle and said mortar reshapeable under feedback control such that the interior surface of at least one of said cradle and said mortar has substantially the same shape as the exterior surface of said tissue specimen; a bed with a surface, said surface preferably convex, over which said tissue specimen is stretched and a vacuum system adapted to gently induce said tissue specimen to releasably adhere to said surface such that said stretching induces a substantially-constant thickness to said tissue specimen; a recess in the walls of said MRI of predetermined shape, said recess adapted to contain said tissue specimen, said recess adapted to reshape said tissue specimen such that the shape of the surface of said tissue specimen is substantially the same as said predetermined shape of said recess such that nothing intervenes between said tissue specimen and said MRI; and a recess in a magnet of said MRI of predetermined shape, said recess adapted to contain said tissue specimen, said recess adapted to reshape said tissue specimen such that the shape of the surface of said tissue specimen is substantially the same as said predetermined shape of said recess such that nothing intervenes between said tissue specimen and said MRI;
the shape of said canister selected from a group consisting of a fixed cross-section with sides perpendicular to the cross-section, a fixed cross-section with sides non-perpendicular to the cross-section, a varying cross-section with sides perpendicular to the cross-section, a varying cross-section with sides non-perpendicular to the cross-section, and any combination thereof, said cross-section selected from a group consisting of a circle, a regular convex polygon with at least 2 and not more than 12 sides, an irregular polygon, a stellate polygon and any combination thereof, said varying cross-section changing in at least one manner selected from a group consisting of changing in cross-sectional size, changing in cross-sectional shape and any combination thereof.

It is another object of the present invention to disclose the system, wherein said containment means additionally comprises a jacket adapted to perform at least one function selected from a group selected from: regulate the temperature of at least a portion of said tissue specimen, and induce hyperpolarization of said tissue specimen without contact between said hyperpolarizing agent and said tissue specimen.

It is another object of the present invention to disclose the system, additionally comprising one or more indicia, said indicia adapted to unambiguously identify at least one region of said near surface of said tissue specimen, said unambiguous identification of said at least one region of said near surface adapted to ensure an unambiguous one-to-one identification between at least one location in said image, said at least one location of said near surface and at least one location within said body, said location within said body adjacent, before excision, to said region of said near surface; at least one of said indicia selected from a group consisting of MRI transparent indicia, MRI opaque indicia, hyperpolarizing indicia and any combination thereof.

It is another object of the present invention to disclose the system, wherein at least one of the following is held true;
a. said indicia are selected from at least one of a group consisting of hyperpolarizing agents, paint, wire, pigment, plaques, and fluorescent materials;
b. the location of said indicia is selected from a group consisting of: said containment means comprises said indicia; said tissue specimen comprises said indicia, said indicia being applied to said tissue specimen before the start of imaging and any combination thereof;
c. at least one of said indicia is selected from a group consisting of: hyperpolarizing agents, paint, wire, plaques, pigment, fluorescent materials, liquid-filled volumes of predetermined shape, gas-filled volumes of predetermined shape, solid-filled volumes within said canister and any combination thereof.

It is another object of the present invention to disclose the system, additionally comprising at least one second imaging means selected from a group consisting of:
a. a thermal camera to thermally image said tissue specimen;
b. an optical imaging system to generate at least one optical image of said surface-proximate tissue of said tissue specimen, said optical imaging system selected from a group consisting of a CCD array, a camera, a photoconductive detector array, a photovoltaic detector array, a quantum dot may, a superconducting single-photon detector array, a photovoltaic cell array, a phototube array, a CT imaging system, an infrared imaging system, a fluorescence imaging system, a visible light imaging system, a UV imaging system and any combination thereof;
c. a PET imaging system to generate a PET image of said surface-proximate tissue of said tissue specimen;
d. an ultrasound imaging system, to generate an ultrasound image of said surface-proximate tissue of said tissue specimen;
e. and any combination thereof;
the image generated by said second imaging means and said MRI image fusible, thereby generating a rendered 3D image of said surface-proximate tissue of said tissue specimen.

It is another object of the present invention to disclose a method of MRI imaging the near surface of at least one tissue specimen, comprising steps of:
a. providing an MRI system for imaging said surface-proximate tissue of said at least one tissue specimen, said MRI system comprising:
   i. an MRI comprising at least two static magnetic field magnets, at least one RF magnetic field magnets and at least one RF receiver coils, said MRI adapted to image only portions of said tissue specimen proximate to the surface of said tissue specimen; and
   ii. a maneuvering controller comprising a processing system, said processing system configured to enable sequential imaging of substantially all of said surface-proximate tissue by controlling maneuvering of at least one member of a group consisting of said static magnetic field magnets, said RF magnetic field magnets, said RF receiver coils, at least one said tissue specimen and any combination thereof such that the volume of interest of said MRI is substantially within said surface-proximate tissue; and
b. maneuvering at least one of said group consisting of said static magnetic field magnets, said RF magnetic field magnets, said RF receiver coils, at least one said tissue specimen and any combination thereof,
thereby holding said volume of interest of said MRI substantially within said surface-proximate tissue by means of at least one of the following:
a. at least one member of said group consisting of static magnetic field magnets, RF magnetic field magnets, RF receiver coils and any combination thereof circumnavigating said tissue specimen around a vertical axis through approximately the center of said tissue specimen, said circumnavigation adapted such that said surface-proximate tissue remains within said volume of interest of the MRI;
b. disposing at least one member of a group consisting of said RF magnetic field magnets, said RF receiver coils and any combination thereof about said tissue specimen in a horizontal planar configuration adapted to at least partially surround said tissue specimen, and maneuvering said at least one member of a group consisting of said RF magnetic field magnets, said RF receiver coils and any combination thereof in at least the direction parallel to a vertical axis through approximately the center of said tissue specimen, such that the volume of interest of said MRI is retained within said surface-proximate tissue;
c. comprising said MRI of at least one packed array of MRI/NMR devices of substantially no fringing magnetic fields, thereby analyzing at least one of adjacent tissue specimens and adjacent portions of said at least one tissue specimen, said system further comprising a pneumatic delivery system adapted to deliver said at least one of adjacent tissue specimens and adjacent portions of said at least one tissue specimen to stages of said packed array, wherein said adjacent MRI/NMR devices differ in at least one of a group consisting of resolution, contrast and signal-to-noise ratio;
d. said processing system is configured to maneuver said specimen in at least two directions; and
e. any combination thereof.

It is another object of the present invention to disclose the method, additionally comprising steps of configuring said system to acquire time-varying MRI images.

It is another object of the present invention to disclose the method, additionally comprising at least one of the following steps;
a. providing said static magnetic field magnets as low-field magnets adapted to create high contrast images, such that images of cancerous tissue appear to be a different intensity from images of non-cancerous tissue; and
b. providing a contrast enhancer, said contrast enhancer increasing over untreated tissue at least one of a group selected from (i) the signal from at least some portion of said surface-proximate tissue of said tissue specimen, and (ii) the difference between at least one response to MRI of cancerous tissue and the same at least one response to MRI of normal tissue;
   selecting said contrast enhancer from a group consisting of a hyperpolarizing agent, a contrast agent and any combination thereof;
   employing said contrast enhancer in a manner selected from a group consisting of (i) comprising said contrast enhancer of a pretreatment fluid and immersing said tissue specimen in said pretreatment fluid; (ii) applying said contrast enhancer to said surface-proximate tissue and any combination thereof;
   treating said tissue with said contrast enhancer in a manner selected from a group consisting of: in-vivo, thereby treating said tissue specimen with said contrast enhancer before excision; ex-vivo, thereby treating said tissue specimen with said contrast enhancer after excision and any combination thereof;
   selecting said in-vivo treatment from a group consisting of: introducing at least one hyperpolarizing agent into said body; contacting at least one hyperpolarization agent with said body and inducing hyperpolarization of at least a portion of said body via said contact; placing at least one hyperpolarization agent proximity to but not in contact with said body and inducing hyperpolarization of at least a portion of said body via said proximity; introducing at least one contrast agent into said body and any combination thereof;
   selecting said ex-vivo treatment from a group consisting of: introducing at least one hyperpolarizing agent into said tissue specimen; contacting said tissue specimen with at least one hyperpolarization agent and thereby inducing hyperpolarization of at least a portion of said tissue specimen via said contact; placing at least one hyperpolarization agent in proximity to but not in contact with said tissue specimen and thereby inducing hyperpolarization of at least a portion of said tissue specimen via said proximity; contacting said tissue specimen and at least one contrast agent, and any combination thereof;
   selecting said contact between said excised tissue and contrast enhancement material from a group consisting of immersing said excised tissue specimen in contrast enhancement fluid, injecting contrast enhancement material into said tissue specimen, coating contrast enhancement material on said excised tissue specimen, and placing contrast enhancement material in close proximity to said tissue specimen.

It is another object of the present invention to disclose the method, additionally comprising steps of selecting said hyperpolarizing agent from a group consisting of water, other hyperpolarizable liquids, ¹²⁹Xe, ³He, anesthetic gas, oxygen, an injectable solution containing ¹³C and any combination thereof.

It is another object of the present invention to disclose the method, additionally comprising steps of selecting said contrast agent from at least one of a group consisting of functional paramagnetic particles (FPP), superparamagnetic iron platinum particles, Gadolinium(III)-containing MRI contrast agents, iron oxide contrast agents, Mn-based nanoparticles, manganese ions (Mn²⁺), SPIO, barium sulfate, air, clay, Perflubron, peptides linked to high payload MRI contrast agents, antibodies linked to high payload MRI contrast agents, small ligands linked to high payload MRI contrast agents, small protein domains linked to high payload MRI contrast agents, peptides linked to MRI contrast agents with high relaxivities, antibodies linked to MRI contrast agents with high relaxivities, small ligands linked to MRI contrast agents with high relaxivities, small protein domains linked to MRI contrast agents with high relaxivities, ³He, ⁷Li, ¹³C, ¹⁹F, ¹⁷O, ²³Na, ³¹P and ¹²⁹Xe.

It is another object of the present invention to disclose the method, additionally comprising steps of:
a. providing containment means for said tissue specimen;
b. selecting said containment means from a group consisting of: a canister of predetermined shape to contain said tissue specimen, said canister adapted to induce said tissue specimen into said predetermined shape; a canister adapted to contain said tissue specimen while retaining substantially unaffected said tissue specimen's shape, said canister either containing only gas or at least partially filled with a liquid, said liquid at least partially supporting said tissue specimen; a cradle and mortar adapted to contain said tissue specimen, said cradle and said mortar reshapeable under feedback control such that the interior surface of at least one of said cradle and said mortar has substantially the same shape as the exterior surface of said tissue specimen; a bed with a surface, said surface preferably convex, over which said tissue specimen is stretched and a vacuum system adapted to gently induce said tissue specimen to releasably adhere to said surface such that said stretching induces a substantially-constant thickness to said tissue specimen; a recess in the walls of said MRI of predetermined shape, said recess adapted to contain said tissue specimen, said recess adapted to reshape said tissue specimen such that the shape of the surface of said tissue specimen is substantially the same as said predetermined shape of said recess such that nothing intervenes between said tissue specimen and said MRI; and a recess in a magnet of said MRI of predetermined shape, said recess adapted to contain said tissue specimen, said recess adapted to reshape said tissue specimen such that the shape of the surface of said tissue specimen is substantially the same as said predetermined shape of said recess such that nothing intervenes between said tissue specimen and said MRI; and
c. selecting the shape of said canister is from a group consisting of a fixed cross-section with sides perpendicular to the cross-section, a fixed cross-section with sides non-perpendicular to the cross-section, a varying cross-section with sides perpendicular to the cross-section, a varying cross-section with sides non-perpendicular to the cross-section, and any combination thereof, said cross-section selected from a group consisting of a circle, a regular convex polygon with at least 2 and not more than 12 sides, an irregular polygon, a stellate polygon and any combination thereof, said varying cross-section changing in at least one manner selected from a group consisting of changing in cross-sectional size, changing in cross-sectional shape and any combination thereof.

It is another object of the present invention to disclose the method, additionally comprising steps of providing a jacket for said canister, said jacket performing at least one function selected from a group selected from: regulate the temperature of at least a portion of said tissue specimen, and induce hyperpolarization of said tissue specimen without contact between said hyperpolarizing agent and said tissue specimen.

It is another object of the present invention to disclose the method, additionally comprising steps of providing one or more indicia; unambiguously identifying at least one region of said near surface of said tissue specimen by means of said indicia, said unambiguous identification of said at least one region of said near surface ensuring an unambiguous one-to-one identification between at least one location in said image, said at least one location of said near surface and at least one location within said body, said location within said body adjacent, before excision, to said region of said near surface; selecting at least one of said indicia from a group consisting of MRI transparent indicia, MRI opaque indicia, hyperpolarizing indicia and any combination thereof.

It is another object of the present invention to disclose the method, additionally comprising at least one of the following steps;
a. selecting said indicia from at least one of a group consisting of hyperpolarizing agents, paint, wire, pigment, plaques, and fluorescent materials;
b. selecting the location of said indicia from a group consisting of: said containment means comprise said indicia; said tissue specimen comprises said indicia, said indicia applied to said tissue specimen before the start of imaging and any combination thereof; and
c. selecting at least one of said indicia from a group consisting of: hyperpolarizing agents, paint, wire, plaques, pigment, fluorescent materials, liquid-filled volumes of predetermined shape, gas-filled volumes of predetermined shape, solid-filled volumes within said canister and any combination thereof.

It is another object of the present invention to disclose the method, additionally comprising steps of providing at least one second imaging means and selecting said at least one second imaging means from a group consisting of;
a. a thermal camera to thermally image said tissue specimen;
b. an optical imaging system to generate at least one optical image of said surface-proximate tissue of said tissue specimen, said optical imaging system selected from a group consisting of a CCD array, a camera, a photoconductive detector array, a photovoltaic detector array, a quantum dot array, a superconducting single-photon detector array, a photovoltaic cell array, a phototube array, a CT imaging system, an infrared imaging system, a fluorescence imaging system, a visible light imaging system, a UV imaging system and any combination thereof;
c. a PET imaging system to generate a PET image of said surface-proximate tissue of said tissue specimen;
d. an ultrasound imaging system, to generate an ultrasound image of said surface-proximate tissue of said tissue specimen;
e. and any combination thereof;
the image generated by said second imaging means and said MRI image fusible, thereby generating a rendered 3D image of said surface-proximate tissue of said tissue specimen.

### BRIEF DESCRIPTION OF THE FIGURES

In order to better understand the invention and its implementation in practice, a plurality of embodiments will now be described, by way of non-limiting example only, with reference to the accompanying drawings, wherein

FIG. 1A-B schematically illustrates the reshaping of the tissue specimen in the prior art;

FIG. 2A-C schematically illustrates tissue specimen containment methods, comparing prior art to the present invention;

FIG. 3 schematically illustrates an MRI where the MRI magnets comprise the walls of the containment;

FIG. 4 schematically illustrates an embodiment of an indirect hyperpolarizing system; and

FIG. 5 schematically illustrates an embodiment of the present system comprising a movable RF transmitter coil assembly and a movable RF receiver coil assembly.

### DETAILED DESCRIPTION OF THE PREFERRED EMBODIMENTS

It is an object of the present invention to disclose a system for imaging the near surface of excised tissue specimens. Various modifications will remain apparent to those skilled in the art, since the generic principles of the present invention have been defined specifically to provide this imaging system.

The term ‘proximate’ hereinafter refers to a distance less than about 10 mm.

The term ‘about’ hereinafter refers to +25% of a value.

The term ‘clean margin’ hereinafter refers to a predetermined thickness of malignancy-free tissue reaching from the surface of excised tissue to a predetermined depth within said excised tissue.

The term ‘volume of interest’ hereinafter refers to the region within the MRI within which imaging occurs.

The term ‘Functionalized Paramagnetic Particle’ or ‘FPP’ refers hereinafter to a particle or probe containing a paramagnetic entity or agent or core and a moiety that is adapted to interact with a target biochemical molecular species or biomarker of interest.

The term ‘paramagnetic core’ used herein refers hereinafter to a paramagnetic species or paramagnetic payload or paramagnetic entity or paramagnetic agent that can include a metal ion, a metal complex, oxides of a metal ion, oxides of a transition metal, mixed oxides of a transition metal, metal complexes, aggregates of metal complexes, polymer-bound metal complexes, stable organic radicals and their mixtures. The metal ion can be selected from a group comprising an on of nickel, iron, manganese, copper, gadolinium, europium and mixtures thereof.

The term ‘nuclear relaxation property’ refers hereinafter to the relaxation of water protons. The effect is a change in magnetic resonance signal, which is measured as a shortening of the longitudinal (T₁, spin-lattice) and transverse (T₂, spin-spin) relaxation times. In one embodiment, the ability of the paramagnetic species to decrease T₁ and T₂ is respectively defined as the transverse and the longitudinal relaxivity. It is herein acknowledged that T₁ times are longer at higher field strengths. Furthermore, the T₁ parameter is not affected by internal magnetic field gradients or by differences in fluid diffusivity. Moreover, instrument artifacts influence T₁ measurements to a much lesser degree than T₂ measurements.

The terms ‘RF magnetic field magnet’ and ‘RF transmitter coil’ will refer hereinbelow, equivalently, to the device which produces the MRI's RF magnetic field.

The present invention discloses a system and method of determining the presence of a clean margin in near real time so that a surgeon can, by determining in near-real time whether excision of further tissue is necessary, ensure that only a single operation is necessary to ensure that all malignancy in or near a tumor is removed from a patient.

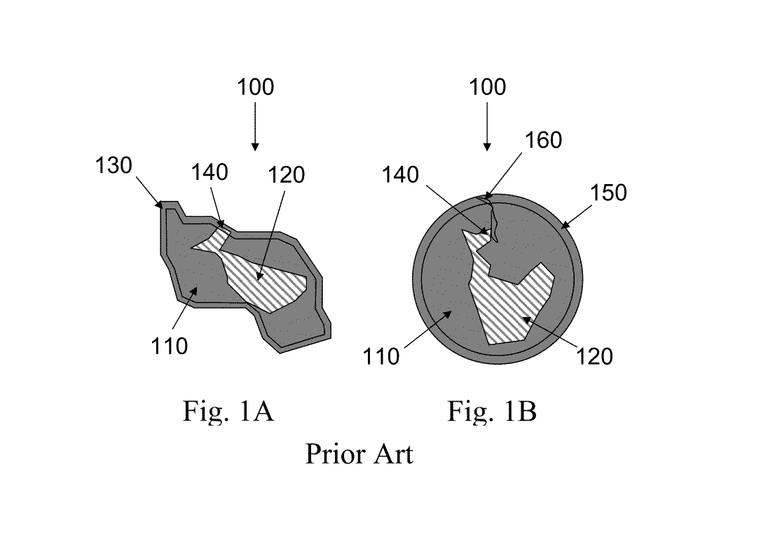

In reference to FIG. 1, in the prior art, a tissue specimen is induced into a canister, preferably a canister shaped like a right circular cylinder, so that it entirely fills the canister and the tissue specimen is forced to assume the shape of the canister. A weakness of the prior art is that, in inducing the tissue specimen to attain the predetermined shape, folding of the tissue can occur. In FIG. 1A, a cross-section of an exemplary tissue specimen 100 is shown, which includes normal tissue 110 and cancerous tissue 120. One portion 140 of the cancerous tissue 120 invades the nominally clear margin 130; this is the portion the system and method are intended to detect. In FIG. 1B, the tissue specimen 100 has been induced into the shape of a right circular cylinder; the circular cross-section of the cylinder is shown. The normal tissue 110 and the cancerous tissue 120 have been reshaped and the tissue specimen has folded during this process; a portion 160 of the external edges is now completely surrounded by tissue. However, the portion 140 of the cancerous tissue 120 requiring detection is not detectable; it is outside the detectable region 150 of the reshaped tissue specimen 100.

Another weakness in the prior art is that there is no means therein of relating a location in a tissue specimen to the location in the body which was adjacent to that location in the tissue prior to excision of the tissue specimen. Therefore, in the prior art, if cancerous cells are detected in the nominally clear margin, further tissue must be excised around the entire periphery of the volume from which the original tissue specimen was excised.

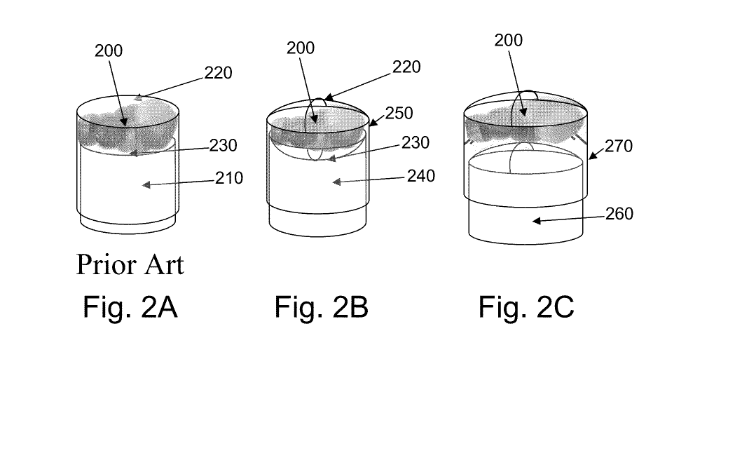

In reference to FIG. 2A, in the prior art, the tissue specimen 200 is reshaped in a canister 210, preferably a right circular cylinder, with flat top 220 and bottom 230. In FIG. 2A-C, for clarity, the tissue specimen is shown unshaped.

In some embodiments (FIG. 2B) of the present system, the tissue specimen 200 is placed in a cradle 240, with a mortar 250 over the tissue specimen; the cradle 240 and mortar 250 are curved (220, 230) and, in some variants, are reshaped to follow the contours of the tissue specimen. In other embodiments (FIG. 2C), the tissue specimen 200 is reshaped by gently stretching it over a bed 260; in some variants, a cover 270 assists in inducing the tissue specimen to have a constant thickness.

In the system used herein, an imaging MRI system with volume of interest approximately the size of the desired clean margin sequentially images the excised tissue until substantially all of the surface has been examined, Malignant (cancerous) tissue images differently from non-malignant (normal) tissue, therefore, portions of the nominally clean margin which contain malignant tissue can be identified.

In some embodiments, the surgeon can then excise a new clean margin around the entirety of the periphery of the existing excision and repeat the test until a true clean margin is found.

In preferred embodiments, the location of the portion or portions of the nominally clean margin with malignant tissue can be referenced back to the location or locations within the patient from which it (or they) were removed, in these preferred embodiments, the surgeon need only excise further tissue in the locations where it is known that there was cancerous tissue in the nominally clean margin, reducing the amount of tissue which needs to be removed from the patient in order to ensure a true clean margin.

Under MRI malignant tissue will provide a different signal from normal tissue. The malignant tissue will have different T₁ and T₂ relaxation times and will also absorb different amount of magnetic energy. The different T₁ and T₂ relaxation times can be detected using a diffusion-weighted signal, or the different amount of absorption can be detected using high-contrast magnets, wherein the cancerous tissue will appear to be a different intensity than the normal tissue. The difference in contrast can be enhanced by low-field magnets, by hyperpolarization of selected tissues, by use of contrast agents, by use of other modalities such as, but not limited to, PET or CT, and by any combination of these.

In the present system, the tissue specimen is placed within an MRI adapted to image thin regions of interest, the MRI comprising static magnetic field magnets, RF magnetic field magnets and RF receiver coils, the magnets enabled to be maneuverable, with maneuvering of the magnets controlled by a processing system. As described hereinbelow, the magnets can be maneuvered separately or in any desired combination. Maneuvering of the magnets under control of the processing system can comprise circumnavigating the specimen, moving vertically along the specimen, moving inward towards the specimen, moving outward from the specimen, and any combination thereof. In preferred embodiments, as described hereinbelow, these movements ensure both that portions of the tissue specimen proximate to the surface remain within the region of interest of the MRI and that substantially all of the near surface of the specimen is sequentially imaged by the MRI.

For systems such as the current one which image thin regions of tissue, the volume of interest of the MRI must be correspondingly thin. Therefore, it is of importance that the portion of tissue of interest, in this case the periphery of the tissue, be within the volume of interest of the MRI. Methods of doing this include inducing the excised tissue specimen into a regular shape so that, as at least one of the RF transmitter coils, the RF receiver coils or the static magnets rotate around the specimen to sequentially image the specimen's periphery, the periphery automatically remains within the volume of interest; maneuvering the magnets so that the periphery of the specimen remains within the volume of interest as its periphery is sequentially imaged; rotating a specimen induced into a regular shape so that, as the specimen rotates, its periphery automatically remains within the volume of interest, maneuvering the specimen so that its periphery remains within the volume of interest as the periphery is sequentially imaged, and any combination of the above.

In some embodiments, the excised tissue is induced into a regular, predetermined shape for imaging. Methods of inducing this regular shape include, but are not limited to, placing the tissue within a canister of regular shape with at least one movable side, such that the tissue entirely fills the interior of the canister; stretching the tissue against a support; pressing the tissue onto a support; pressing the tissue between two supports; and any combination thereof.

Some embodiments of a system for MRI imaging the near surface of at least one tissue specimen comprise an MRI comprising a group of magnets comprising static magnetic field magnets, RF magnetic field magnets and RF receiver coils, with the MRI adapted to image only portions of the tissue specimen proximate to the surface of the tissue specimen; and a processing system adapted to control maneuvering of at least one of the magnets in the group of magnets such that the tissue specimen is static and at least one of the magnets in the group of magnets moves, thereby sequentially imaging substantially all of the surface-proximate tissue.

In some embodiments, the processing system is adapted to cause any combination of the group of magnets disposed about the tissue specimen in a horizontal planar configuration adapted to at least partially surround the tissue specimen to circumnavigate the tissue specimen around a vertical axis through approximately the center of the tissue specimen, the circumnavigation adapted to retain the volume of interest of the MRI within the surface-proximate tissue.

It is another object to disclose a device for MRI imaging the near surface of at least one tissue specimen, working in a method of providing the MRI system disclosed above and maneuvering at least one of the group consisting of static magnetic field magnets, RF magnetic field magnets, RF receiver coils and any combination thereof, thereby sequentially imaging substantially all of the surface-proximate tissue.

It is another object to disclose the device working in the above method, wherein the maneuvering causes at least one of the group consisting of static magnetic field magnets, RE magnetic field magnets, RF receiver coils and any combination thereof to circumnavigate the tissue specimen around a vertical axis through approximately the center of the tissue specimen, the circumnavigation adapted such that the surface-proximate tissue remains within the volume of interest of the MRI.

It is another object to disclose the device working in the above method, the method comprising additional steps of providing one or more members of a group consisting of RF magnetic field magnets, RF receiver coils and any combination thereof; and disposing one or more members of the group consisting of RF magnetic field magnets, RF receiver coils and any combination thereof about the tissue specimen in a horizontal planar configuration adapted to at least partially surround the tissue specimen, wherein one direction of maneuvering is parallel to a vertical axis through approximately the center of the tissue specimen.

In embodiments where a canister is used to induce the tissue into a regular shape, preferably, the canister is cylindrical so that, after circunmavigating the sides of the shape, laying the canister on its side will enable imaging the top and bottom in two images. Examples of the cross-section of such a cylindrical canister include, but are not limited to, a circle, a regular polygon, and an irregular polygon, which can be non-symmetrical. Preferably, the polygon has between 2 and 12 sides and, more preferably, comprises a hexagon, which maximizes the number of canisters per unit area. Irregular polygons include, but are not limited to, semicircular cross-sections and stellate shapes.

In some embodiments, the canister's cross-sectional shape changes in the vertical direction. Canisters can become larger or smaller in the vertical direction, and the shape of the cross-section can vary along the vertical axis. The sides of the canister are preferably at a right angle to its base and the top, but, in some embodiments, the sides are not at a right angle to the base or the top. In preferred embodiments, the top of the canister is parallel to the base; in some embodiments, the top is at an angle not parallel to the base. In yet other embodiments, the top is not flat, preferably firming a segment of a sphere, convex downward.

In yet other embodiments, the containment for the tissue specimen is an integral part of the MRI. Examples of such embodiments, include, but are not limited to: the MRI magnets comprise the walls of the containment, the containment comprises a recess on top of or within the top of one of the magnets, and any combination thereof.

In some embodiments, the system comprises an MRI imaging system adapted to image only portions of a tissue specimen proximate to the surface of the tissue specimen; and a canister of hexagonal cross-section to contain the tissue specimen wherein the number of canisters per unit area is maximized.

It is another object to disclose a device for MRI imaging the surface-proximate tissue of a tissue specimen excised from a body, the device working in a method of providing a system for MRI imaging surface-proximate tissue of at least one tissue specimen excised from a body, the system as disclosed above; inducing the tissue specimen into the canister; and imaging the surface-proximate tissue of the tissue specimen thereby maximizing the number of canisters per unit area.

In some embodiments, the system comprises an MRI imaging system adapted to image only portions of tissue specimen proximate to the surface of the tissue specimen; and a canister to contain the tissue specimen, the canister having its shape defined by a group consisting of having constant cross-section along at least one longitudinal axis, the constant cross-section being non-symmetrical; and having a vertical longitudinal axis, the cross-section of the canister changing along the vertical longitudinal axis wherein the canister can more efficiently hold irregularly shaped tissue specimens.

The system as disclosed above, wherein the changing cross-section changes in a manner selected from a group consisting of changes in cross-sectional size, changes in cross-sectional shape and any combination thereof.

It is another object to disclose a device for MRI imaging the surface-proximate tissue of a tissue specimen excised from a body, the device working in a method of providing a system for MRI imaging surface-proximate tissue of the tissue specimen excised from the body, as disclosed above; inducing the tissue specimen into the canister; and imaging the surface-proximate tissue of the tissue specimen.

It is another object to disclose the device working in the method as disclosed above, the method comprising an additional step of varying the cross-section by changing cross-sectional size, changing cross-sectional shape, and any combination thereof.

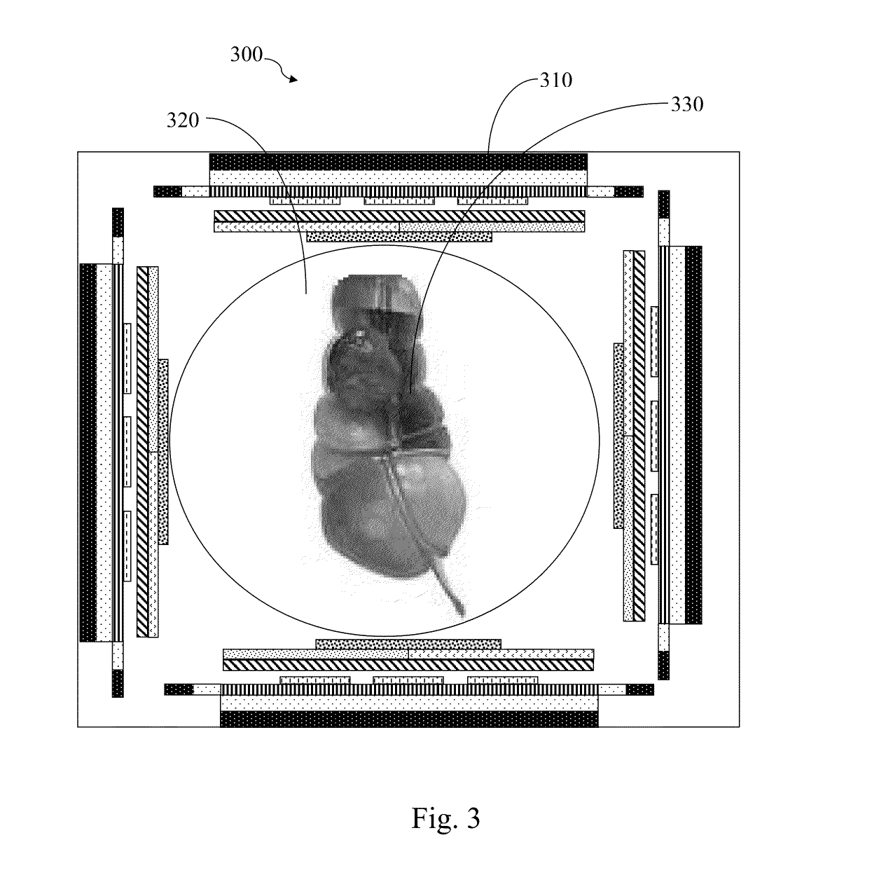

In reference to FIG. 3, a non-limiting example is shown of an MRI 300 where the MRI magnets 310 comprise the walls of the containment 320; the tissue specimen 330 is held within containment 320 by any of the methods disclosed hereinbelow.

In FIG. 3, the specimen retains its natural shape; in other embodiments, the specimen is induced into a recess in at least one of the walls of the containment 320, in yet other embodiments, the walls of the containment 320 are movable such that the walls 320 induce the specimen into a regular shape.

In some embodiments, the system comprises: an MRI imaging system adapted to image only portions of a tissue specimen proximate to the surface of the tissue specimen, the MRI imaging system characterized by a recess of predetermined shape adapted to contain the tissue specimen, the recess further adapted to reshape the tissue specimen such that the shape of the surface of the tissue specimen is substantially the same as the predetermined shape wherein nothing intervenes between the tissue specimen and the MRI.

It is another object to disclose a device for MRI imaging the surface-proximate tissue of a tissue specimen excised from a body, the device working in a method of providing an MRI imaging system adapted to image only portions of the tissue specimen proximate to the surface of the tissue specimen, as disclosed above; inducing the tissue specimen into the recess, such that the tissue specimen attains substantially the predetermined shape; and imaging the surface-proximate tissue of the tissue specimen, thereby enabling imaging wherein nothing intervenes between the tissue specimen and the MRI.

In some embodiments where at least one of the RF transmitter coils, the RF receiver coils or the static magnets is moved, the sample is rotated to sequentially image its near-surface regions; in these embodiments, the volume of interest moves linearly to track the periphery. In other embodiments where at least one of the RF transmitter cods, the RF receiver coils or the static magnets is moved, the sample is stationary and the volume of interest circumnavigates the sample, tracking the periphery as it does so.

In some embodiments, at least one of the RF transmitter coils, the RF receiver coils or the static magnets is moved. In some of these embodiments, the tissue is induced into a fixed shape, and the moving magnets simply circumnavigate the sample, following the perimeter of the fixed shape.

In other embodiments, at least one of the RF transmitter coils, the RF receiver coils or the static magnets is moved, under feedback control, to position the volume of interest in the near-surface portions of the excised tissue during circumnavigation. In these embodiments, a second modality can be used to identify the location of the surface of the tissue. The second modality can be, but is not limited to, a camera, an ultrasound sensor, a photon detector, or any other means known in the art for detecting surfaces and/or edges. The second modality can image a region and identify the boundary of the tissue by imaging, it can detect reflected signals, detect transmitted signals, determine the time required for reflected signal to reach a detector, determine time differences between signals reaching different detectors, or use any other means known in the art to detect surfaces and edges.

In some embodiments, the movable magnets image a two-dimensional (2D) region of the near-surface of the excised tissue; in such embodiments the moving magnets at least partially circumnavigate the excised tissue.

In other embodiments, the movable magnets image a one-dimensional (1D) region of the near-surface, preferably at least part of a ring around the surface. In these embodiments, the movable magnets move at least upward along the surface, sequentially imaging horizontal slices of the near-surface regions of the tissue.

In some embodiments imaging a 1D region, the movable magnets can also translate laterally under feedback control so that the ring can be irregular, with the profile of the volume of interest formed by the ring movable to follow the profile of the excised tissue.

In some embodiments, in an MRI adapted to image only portions of the tissue specimen proximate to the surface of the tissue specimen, with a processing system adapted to sequentially image the surface-proximate tissue, the static magnets are low-field magnets, with magnetic field less than about 2 Tesla, adapted to create a high contrast image, such that images of cancerous tissue appear to be a different intensity than images of normal (non-cancerous) tissue.

It is another object to disclose a device for MRI imaging the near surface of at least one tissue specimen, working in a method of providing the MRI system disclosed above; and sequentially imaging substantially all of the surface-proximate tissue, thereby providing at least one image in which images of cancerous tissue appear to be a different intensity from images of non-cancerous tissue.

In preferred embodiments, the static field magnets are designed to have very low or no fringing fields, so that MRI imaging devices can be placed adjacent to each other. Adjacent devices can differ in magnetic field strength or location of volume of interest, or can image different regions of the excised tissue specimen, and any combination thereof.

Contrast agents can be used to increase the contrast of the sample. The contrast agents can be introduced into the tissue specimen either before or after its excision. Preferably, the contrast agents are designed to preferentially bind to cancerous cells, thereby differentiating the cancerous cells from normal cells. Contrast agents can be, but are not limited to, functional paramagnetic particles (FPP); Gadolinium (III) containing MRI contrast agents; iron oxide contrast agents; Mn-based nanoparticles; superparamagnetic iron oxide (SPIO), ultrasmall superparamagnetic iron oxide (USPIO), barium sulfate, air and clay to lower T₂ signal: Perflubron, a type of perfluorocarbon; and hyperpolarizing materials.

Some preferred embodiments are based on appropriately designed functionalized paramagnetic particles (FPP), preferably liposomes, containing a paramagnetic core or paramagnetic species and a moiety/moieties, which is/are specifically designed to interact and/or be responsive to the target biomarker or biochemical molecular species or analyte of interest.

The use of paramagnetic species allows determining different concentrations of i.e. a biomarker or analyte of interest within the tested sample, thus affecting for example the assessment of the difference between healthy and diseased tissues. Gadolinium (Gd) based contrast agents are the most used systems. In some embodiments, the molecular magnetic resonance protocols are capable of detecting epitopes that are present at very low concentrations (typically in the 50-100 nmol/L range).

In an embodiment of the invention, the paramagnetic entity, agent, or core constitutes a non ferrous oxide metal ion. According to certain embodiments, the paramagnetic entity, agent, or core comprises a metal ion, including oxides of a metal ion, oxides of a transition metal, mixed oxides of a transition metal and their mixtures. More specifically, the metal ion ma be selected from a group consisting of an ion of nickel, manganese, copper, gadolinium, dysprosium, europium and any combination thereof.

In another embodiment of the invention, the FPP can include a moiety or residue adapted to specifically interact with a target biochemical molecular species or biomarker of interest. Such a moiety or residue may comprise a receptor, or ligand, or any compound, such as a biomolecule or a small molecule, an antibody or an antigen-binding fragment that binds specifically to a selected target molecule or analyte. In specific embodiments, a moiety or residue may comprise a macromolecule, a peptide, a hormone, a fatty acid, a lipid, a receptor agonist and/or antagonist, an amino acid, a sugar, lectins, albumins, polycarbon molecules, glycoproteins, nucleic acids, PEGylated molecules (molecules attached to Polyetheylene Glycol chains), liposomes, chelators, cells, viruses, chemotherapeutic agents, biotin, streptavidin and any combination thereof. In preferred embodiments of the invention, such functional moieties or residues as herein described are configured to confer the FPP with molecular specificity, such that the change in the measured T₁ nuclear relaxation property correlates with the presence and/or concentration of the target biochemical molecular species or biomarker of interest or to a collective property of the specimen.

In some embodiments of the system, the method as disclosed herein further comprises steps of analyzing at least one characteristic or property of the target molecular species selected from a group comprising concentration, permeability, oxidation state, redox characteristic (reduction-oxidation state), activation state and any combination thereof.

Thus, in one aspect, the system and method of the present invention is directed to detecting a biochemical molecule(s) or biochemical molecular species in a sample by measuring a change in the T₁ nuclear relaxation property of the sample, operated by an interaction between Functionalized. Paramagnetic Particles (FPP) and the biochemical molecular species, in the applied magnetic field. The aforementioned change in T₁ nuclear relaxation property is correlated to the presence of the target biochemical molecular species in the sample.

In another aspect, the invention is directed towards novel combinations of T₁ and T₂ measurements, for example, to detect the presence and/or concentration of a biochemical molecular species or analyte of interest in a sample. In one embodiment, these combinations of T₁ and T₂ measurements may provide synergistic effects with respect to detection and characterization of a target biochemical molecular species.

It is still in the scope of the present invention to provide the method as defined above, wherein the FPP are formed as a single molecule, a multimeric system, a micro-sized vesicle or particle, a nano-sized vesicle or particle, a liposome, a probe and any combination thereof.

It is still in the scope of the present invention to provide the method as defined above, comprising an additional step of selecting the carrier for the FPP from a group consisting of a liquid, a gas, a slurry, a liquid containing particulates, a gas containing particulates, a gel, sol, a suspension, a solution, a dispersion, a colloid, a mixture, an emulsion, an aerosol, a liquid containing solid objects, a gas containing solid objects, and any combination thereof.

Most clinically used MRI contrast agents work through shortening the T₁ relaxation time of protons located nearby. T₁ shortens with an increase in rate of stimulated emission from high energy states (spin anti-aligned with the main field) to low energy states (spin aligned). Thermal vibration of the strongly magnetic metal ions in the contrast agent creates oscillating electromagnetic fields at frequencies corresponding to the energy difference between the spin states (via E=hv), resulting in the requisite stimulation.

MRI contrast agents may be administered by injection into the blood stream or orally, depending on the subject of interest. Oral administration is well suited to tissues from the G.I. tract, while intravascular administration proves more useful for other tissues.

Typical contrast agents include, but are not limited to, Gadolinium(III)-containing MRI contrast agents; iron oxide contrast agents; Mn-based nanoparticles; barium sulfate, air and clay to lower T₂ signal; and Perflubron, a type of perfluorocarbon, which works by reducing the number of hydrogen ions in a body cavity, thus causing it to appear dark in the images.

Gadolinium-containing contrast agents include, but are not limited to: Gadocoletic acid, Gadomelitol, Gadomer 17, gadoterate (Dotarem), gadodiamide (Omniscan), gadobenate (MultiHance), gadopentetate (Magnevist, Magnegita, Gado-MRT ratiopharm), gadoteridol (ProHance), gadoversetamide (OptiMARK), gadoxetate (Primovist), gadobutrol (Gadovist), gadofosveset (Ablavar, formerly Vasovist), and gadoxetate (Eovist).

Two types of iron oxide contrast agents exist: superparamagnetic iron oxide (SPIO) and ultrasmall superparamagnetic iron oxide (USPIO). These contrast agents consist of suspended colloids of iron oxide nanoparticies and, when injected during imaging, reduce the T₂ signals of absorbing tissues, SPIO and USPIO contrast agents can be used, for example, for liver tumor enhancement. Iron oxide contrast agents include, but are not limited to: Feridex I.V. (also known as Endorem and ferumoxides), Resovist (also known as Cliavist), Sinerem (also known as Combidex), Lumirem (also known as Gastromark), and Clariscan™ (also known as PEG-fero, Feruglose, and NC100150).

Superparamagnetic iron platinum particles (SIPPs) have been reported and had significantly better T₂ relaxivities compared with the more common iron oxide nanoparticies. SIPPs were also encapsulated with phospholipids to create multifunctional SIPP stealth immunomicelles that specifically targeted human prostate cancer cells. For example, multifunctional SIPP micelles can also be conjugated to a monoclonal antibody against prostate-specific membrane antigen, thereby specifically targeting human prostate cancer cells in vitro.

Manganese chelates such as Mn-DPDP can be used to enhance the T₁ signal and have been used for the detection of liver lesions. The chelate dissociates in-vivo into manganese and DPDP, with the former being absorbed intra-cellularly and excreted in bile, while the latter is eliminated via the renal filtration.

Manganese ions (Mn²⁺) are also used as a contrast agent, usually referred to as MEMRI (Manganese Enhanced MRI), due to the ability of Mn²⁺ to enter cells through Calcium Ca²⁺ channels.

Contrast agents such as peptides, antibodies, or small ligands, and small protein domains, such as HER-2 affibodies, can achieve targeting. To enhance the sensitivity of the contrast agents, these targeting moieties are usually linked to high-payload MRI contrast agents or MRI contrast agents with high relaxivities. One example of increasing targeting is attaching these contrast agents to FPP's, as described hereinabove.

Other contrast agents include small particles of iron oxide, fullerenes encapsulating Gd³⁺ ions (gadofullerenes) and single-walled carbon nanotube nanocapsules encapsulating Gd³⁺ ion clusters (gadonanotubes), and use of MRI-responsive materials such as ³He, ⁷Li, ¹³C, ¹⁹F, ¹⁷O, ²³Na, ³¹P and ¹²⁹Xe. ²³Na and ³¹P are naturally abundant in the body, so can be imaged directly.

Any of the above contrast agents can be used, as appropriate for the tumor and the means of application, as discussed hereinbelow, for any embodiment disclosed herein which employs a contrast agent.

Hyperpolarization is the selective polarization of nuclear spin in atoms to a level far beyond the polarization seen in normal thermal equilibrium. Hyperpolarization is commonly applied to gases such as ¹²⁹Xe and ³He which are then used, for instance, in hyperpolarized magnetic resonance imaging (MRI) of the lungs. Other methods for hyperpolarization include Dynamic Nuclear Polarization (DNP) for solid materials at cryogenic temperatures and para-hydrogen used in chemical reactions in liquid solutions (PHIP). DNP of nuclei like ¹³C or ¹⁵N at typically ≈1 K can be coupled with subsequent rapid dissolution yielding a room temperature solution containing hyperpolarized nuclei. This liquid can be used in in-vivo metabolic imaging for oncology and other applications. The ¹³C polarization level in the solid is reported as e.g. (64±5)% for a specific setup, and the losses during dissolution and transfer of the sample for actual NMR or MRI measurements can be minimized to a few percent.

In some embodiments, hyperpolarized materials are introduced into the body by inhalation or by injection, for example, via injectable solutions containing ¹³C.

In some embodiments, the hyperpolarized gas is produced in situ, in the patient, before excision of the tissue specimen. In these embodiments, a system is provided for hyperpolarizing unpolarized gas within the patient, comprising hyperpolarization means for hyperpolarizing the unpolarized gas.

According to another embodiment a system for hyperpolarizing gas imaging confined within a volume is disclosed, the volume having a medium therein.

The system comprises (a) at least one volume confining an unpolarized gas and at least one medium; and, (b) hyperpolarization means for hyperpolarizing the unpolarized gas where the hyperpolarization of the unpolarized gas is provided-within the confined volume.

According to another embodiment, the system as defined above additionally comprises a chamber in fluid communication with the volume, the chamber accommodating at least one patient, such that the hyperpolarized gas is supplied from the volume to the chamber.

Indirect hyperpolarization of unpolarized liquid can be provided in vitro within a liquid-tight chamber without liquid communication between the polarized medium and the unpolarized liquid. The proximity of the polarized medium to the unpolarized liquid will result in polarization of the unpolarized liquid.

Hyperpolarization means include, but are not limited to, lasers, ultrasound, RF, microwave, application of heat and any combination thereof.

The medium can be selected from a group including, but not limited to, anesthetic gas, water, oxygen, Helium, Xenon and any combination thereof.

According to another embodiment, the polarized liquid confined within a volume comprising at least one polarized medium and an unpolarized medium (namely a polarized liquid and unpolarized water). Once the polarized liquid and the unpolarized water are in liquid communication, the unpolarized water will polarize.

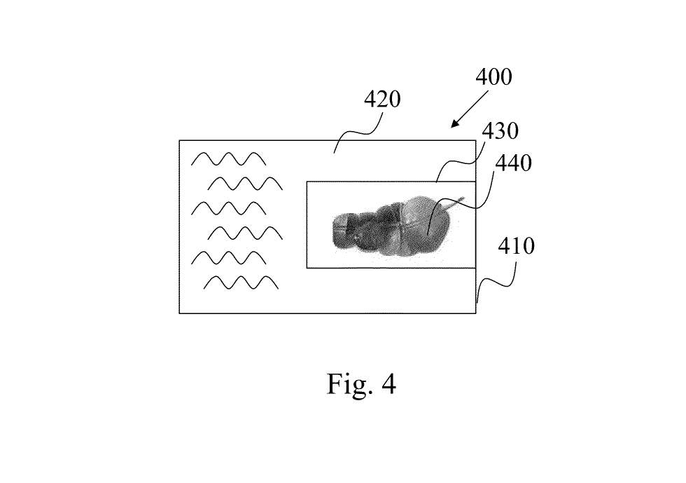

Reference is now made to FIG. 4, schematically illustrating a preferred embodiment of an indirect hyperpolarizing system.

The system 400 for indirectly hyperpolarizing an unpolarized liquid comprises at least one volume 410 confining a polarized medium 420; the volume 410 comprising at least one liquid-tight chamber 430; the chamber 430 configured in size and shape for accommodating a tissue specimen 440 containing unpolarized liquid wherein the indirect hyperpolarization of the unpolarized liquid is provided within the liquid tight chamber without liquid communicating between the polarized medium and the unpolarized liquid.

In preferred variants of the embodiments disclosed herein the tissue specimen can additionally be treated either in-vivo, before excision, or ex-vivo, after excision, with a means of increasing contrast, the contrast enhancement means including, but not limited to, a contrast agent, a hyperpolarizing agent, a fluorescing agent, and any combination thereof. In-vivo treatment can include injecting the specimen with contrast-enhancement means, injecting the patient with contrast-enhancement means, placing the specimen in close proximity to the contrast-enhancement means or placing the patient in close proximity to the contrast-enhancement means. Ex-vivo treatment can include immersion of the tissue specimen in a fluid, pouring fluid over a tissue specimen, painting, spraying or otherwise coating a contrast agent onto the tissue specimen, injecting the contrast agent into the tissue specimen, placing the tissue specimen in close proximity to treatment material and any combination thereof.

Examples of methods of treating the tissue in-vivo include, but are not limited to: introducing hyperpolarizing agents into the body, inducing hyperpolarization in the body via contacting the body with hyperpolarizing agents, inducing hyperpolarization in the body via placing the body in proximity to hyperpolarizing agents without contact between the body and the hyperpolarizing agents, and introducing contrast agents into the body.

Examples of methods of treating the tissue ex-vivo include, but are not limited to: introducing hyperpolarizing agents into the tissue, inducing hyperpolarization in the tissue via contacting the tissue with hyperpolarizing agents, inducing hyperpolarization in the tissue via placing the tissue in proximity to hyperpolarizing agents without contact between the tissue and the hyperpolarizing agents, and introducing contrast agents into the tissue.

Some embodiments of the system comprise an MRI imaging system adapted to image only portions of the tissue specimen proximate to the surface of a tissue specimen; and either an in vivo tissue treatment means consisting of at least one of: hyperpolarizing agents adapted to be introduced into the body; hyperpolarization agents adapted to contact the body, the hyperpolarization agents adapted to induce hyperpolarization of at least a portion of the body via contact; hyperpolarization agents adapted to be placed in proximity to but not in contact with the body, the hyperpolarization agents adapted to induce hyperpolarization of at least a portion of the body via proximity; contrast agents adapted to be introduced into the body; and an ex-vivo tissue treatment means consisting of at least one of: hyperpolarizing agents adapted to be introduced into the tissue specimen; hyperpolarization agents adapted to contact the tissue specimen, the hyperpolarization agents adapted to induce hyperpolarization of at least a portion of the tissue specimen via contact; hyperpolarization agents adapted to be placed in proximity to but not in contact with the tissue specimen, the hyperpolarization agents adapted to induce hyperpolarization of at least a portion of the tissue specimen via proximity; and contrast agents adapted to be introduced into the tissue specimen; wherein either the in vivo tissue treatment means or the ex-vivo tissue treatment means is adapted to increase over untreated tissue the difference between at least one response to MRI of cancerous tissue and the same at least one response to MRI of normal tissue.

In the embodiments of the system disclosed herein, either of the in-vivo tissue treatment means or the ex-vivo tissue treatment means is adapted to preferentially affect at least one of the surface of the tissue specimen and the near surface of the tissue specimen.

In the embodiments of the system disclosed herein, the ex-vivo tissue treatment means comprises at least one of a contrast enhancement fluid adapted to immerse the excised tissue specimen therein, contrast enhancement material adapted to be injected into the tissue specimen, contrast enhancement material adapted to be coated on the excised tissue specimen, and contrast enhancement material adapted to be placed in close proximity to the tissue specimen.

It is another object to disclose a device for treating a tissue specimen to be MRI imaged, the tissue specimen excised from a body, the device working in a method of providing the system for treating the tissue specimen to be MRI imaged disclosed above. For the in-vivo tissue treatment means, applying an in-vivo tissue treatment means to at least a portion of the body in-vivo, thereby causing at least a portion of the tissue specimen to have increased difference over untreated tissue between cancerous tissue and normal tissue in at least one response to MRI; and excising the tissue specimen from the body. For an ex-vivo tissue treatment means, excising the tissue specimen from the body; and applying the tissue treatment means to the tissue specimen ex-vivo, thereby causing at least a portion of the tissue specimen to have increased difference over untreated tissue between cancerous tissue and normal tissue in at least one response to MRI. After applying either the in-vivo or the ex-vivo treatment, imaging the tissue specimen.

It is another object to disclose the device working in the method disclosed above, the method comprising an additional step of adapting one of the in-vivo tissue treatment means and the ex-vivo tissue treatment means to preferentially affect at least one of a group consisting of the surface of the tissue specimen and the near surface of the tissue specimen.

It is another object to disclose the device working in the method disclosed above, the method comprising an additional step of selecting the ex-vivo tissue treatment means from a group consisting of immersing the tissue specimen in contrast enhancement fluid, injecting contrast enhancement material into the tissue specimen, coating the tissue specimen with contrast enhancement material, and placing the tissue specimen in close proximity to contrast enhancement material.

Some embodiments of the system comprise an MRI imaging system adapted to image only portions of the tissue specimen proximate to the surface of a tissue specimen; and at least one contrast enhancement means adapted to increase contrast in the image wherein the contrast enhancement means is adapted to treat the tissue specimen in-vivo before excision or ex-vivo after excision.

In preferred embodiments of the system as disclosed herein, the contrast enhancement means is adapted to preferentially affect at least one of the surface of the tissue specimen and the near surface of the tissue specimen.

It is another object to disclose a device for MRI imaging the near surface of at least one tissue specimen excised from a body, the device working in a method of providing the system for MRI imaging surface-proximate tissue of at least one tissue specimen as disclosed above; selecting at least one of one of in-vivo treatment and ex-vivo treatment of the tissue specimen; for in-vivo treatment, treating the tissue specimen in-vivo with contrast enhancement means before excision and excising the tissue specimen from the body; for ex-vivo treatment, excising the tissue from the body and treating the tissue ex-vivo with the contrast enhancement means after excision; and imaging the tissue specimen.

It is another object to disclose the device working in the method disclosed above, the method comprising an additional step of adapting the contrast enhancement means to preferentially affect at least one of the surface of the tissue specimen and the near surface of the tissue specimen.

It is another object to disclose the device working in the method disclosed above, the ex-vivo treatment comprising an additional step selected from a group consisting of immersing the tissue specimen in contrast enhancement means, coating the tissue specimen with contrast enhancement means, injecting contrast enhancement means into the tissue specimen, and any combination thereof.

In preferred embodiments, means are provided by which a location in an image of the near-surface of the tissue specimen can unambiguously be identified with a location in the body; the location in the body having been adjacent, before excision, to a location on the tissue specimen. In preferred embodiments, the location in the image is also unambiguously identifiable with a location in the tissue specimen.

In some embodiments, the system comprises an MRI imaging system adapted to image only surface-proximate portions of a tissue specimen, and one or more indicia introduced onto or into the tissue specimen, the indicia adapted to unambiguously identify at least one region of the near surface of the tissue specimen. This at least one indicia can be introduced before excision of the tissue specimen, after excision of the tissue specimen, or both; indicia are applied before the start of imaging of the specimen. The indicia, which provide an unambiguous identification of at least one region of the near surface, is adapted to ensure an unambiguous one-to-one identification between at least one location in the image, at least one location of the near surface and at least one location within the body, the location within the body adjacent, before excision, to the region of the near surface. The indicia can be on the surface of the tissue specimen, in the near surface, or in the interior. Indicia can be MRI transparent, MRI opaque, hyperpolarizing, and any combination thereof.

The indicia can be selected from a mark, a figure, a number, a text, a code, a barcode, and any combination thereof.

In some embodiments, the indicia comprise hyperpolarizing agents, paint, pigment, or fluorescent material. In some embodiments, the indicia comprise wires or plaques, thereby providing a set of 3D axes unambiguously referable back to the original location and orientation of the issue specimen, or the wires or plaques can provide a set of known positions within or on the tissue and unambiguously referable back to the original location and orientation of the issue specimen. Indicia can comprise any combination of the above.

In some embodiments, the wires comprise labels or markings which uniquely identify each wire and, by means of the locations of the uniquely identified wires in MRI or other images, enable determination of an unambiguous one-to-one relationship between locations in the image and locations in the tissue.

In some embodiments, the plaques comprise labels, markings or holes uniquely identifying each plaque and, by means of the locations of the uniquely identified plaques in MRI or other images, enable determination of an unambiguous one-to-one relationship between locations in the image with locations in the tissue.

In some embodiments, the at least one indicia are sprayed, painted or otherwise coated onto or into the near surface of the tissue specimen. The surface indicia can provide a set of 3D axes unambiguously referable back to the original location and orientation of the issue specimen; the surface indicia can provide a set of labels uniquely identifying locations on or near the surface and unambiguously referable back to the original location and orientation of the issue specimen; or both.

A non-limiting example of a set of labels is letters running in one direction and numbers in a perpendicular direction, such that the each letter-number pair uniquely identifies a location on the surface. In preferred embodiments, the location thus identified is approximately the size of a voxel of the imaging system, so that there is a one-to-one relationship between surface voxels and letter-number pairs.

In some embodiments of the indicia, the indicia are divided when the tissue is excised, with parts of the indicia remaining in the patient and parts being excised. In these embodiments, the indicia are detectable by the surgeon, thereby providing an unambiguous identification between locations on the excised tissue, locations in the image and locations in the body of the patient.

It is another object to disclose a device for MRI imaging the near surface of at least one tissue specimen excised from a body, working in a method of providing a system for MRI imaging the near surface of at least one tissue specimen, comprising an MRI imaging system as disclosed above and one or more indicia on the tissue specimen, the indicia adapted to unambiguously identify at least one region of the near surface of the tissue specimen; applying the indicia to the tissue specimen before the start of sequential imaging; and sequentially imaging the surface proximate tissue thereby providing an unambiguous one-to-one identification between at least one location in the image, at least one location of the near surface of the tissue specimen and at least one predetermined location within the body, the location within the body adjacent, before excision, to the location of the near surface.

It is another object to disclose the device working in the method disclosed above, the method comprising an additional step of selecting the indicia from at least one of a group consisting of MRI transparent indicia, MRI opaque indicia, and hyperpolarizing indicia.

It is another object to disclose the device working in the method disclosed above, the method comprising an additional step of selecting indicia from a group consisting of hyperpolarizing agents, paint, wire, plaques, pigment, fluorescent materials and any combination thereof.

In other embodiments, the at least one indicia is applied to the canister, as identifiers painted, sprayed-on, adhered or connected to the canister by any means known in the art. The identifiers can be connected to the inside of the canister, the outside, and any combination thereof.

In yet other embodiments, the at least one indicia can form an integral part of the canister. The indicia can be embossing on or in the canister material; can be doping of the canister material; can be reservoirs or cavities of predetermined shape within or on the canister, with the reservoir or cavity being empty (and being visible to the imaging device as a non-responding portion of the image) or the reservoirs or cavities can be filled with a material (such as water or another liquid, or a solid or gas) of predetermined shape that responds strongly to at least one imaging modality; any other method known in the art of integrally connecting indicia with containers can be used; and any combination thereof.

In all cases, indicia and tissue specimen are linked before analysis. This remains true whether the indicia are applied to or form part of the canister or other container, or whether the indicia are applied to the tissue specimen or are introduced into the tissue specimen. However the indicia are linked to the tissue specimen, the linkage is made before the tissue specimen is analyzed.

In some embodiments, the system comprises an MRI imaging system adapted to sequentially image only surface-proximate portions of a tissue specimen, a canister of predetermined shape to contain the tissue specimen, the canister inducing the tissue specimen into the predetermined shape; and indicia on the canister, the indicia adapted to uniquely identify at least one region of the near surface wherein the indicia are adapted to ensure, for at least one location in the image, unambiguous, one-to-one correlation between the at least one location in the image and a corresponding at least one location in the tissue specimen.

In some embodiments, at least one of the indicia is selected from a group consisting of MRI transparent indicia, MRI opaque indicia, hyperpolarizing indicia and any combination thereof.

In some embodiments, at least one of the indicia is comprised of a member of a group consisting of hyperpolarizing agents, paint, wire, plaques, pigment, fluorescent materials, liquid-filled volumes within the canister of predetermined shape, gas-filled volumes within the canister of predetermined shape, solid-filled volumes within the canister of predetermined shape and any combination thereof.

In some embodiments, the predetermined shaped canister is selected from a group consisting of a fixed cross-section with sides perpendicular to the cross-section, a fixed cross-section with sides non-perpendicular to the cross-section, a varying cross-section with sides perpendicular to the cross-section, a varying cross-section with sides non-perpendicular to the cross-section, and any combination thereof. The cross-section itself consists of at least one of a group consisting of a circle, a convex polygon with at least 2 and not more than 12 sides, a stellate polygon and any combination thereof.

It is another object to disclose a device for MRI imaging the near surface of at least one tissue specimen excised from a body, working in a method of providing a system for MRI imaging near-surface tissue in the at least one tissue specimen, comprising an MRI imaging system as disclosed above, a canister of predetermined shape to contain the tissue specimen; and indicia on the canister, the indicia adapted to uniquely identify at least one location in the surface-proximate tissue; providing a canister of predetermined shape, marked with indicia; placing the tissue specimen in the canister, thereby inducing the tissue specimen into the shape of the canister; and sequentially imaging surface-proximate portions of the tissue specimen thereby providing, for at least one location in the image, an unambiguous one-to-one correlation between at least one location in the image and a corresponding at least one location in the surface-proximate tissue.

It is another object to disclose the device working in the method disclosed above, the method comprising an additional step of providing indicia selected from a group consisting of MRI transparent indicia, MRI opaque indicia, hyperpolarizing indicia and any combination thereof.

It is another object to disclose the device working in the method disclosed above, the method comprising an additional step of providing indicia selected from a group consisting of hyperpolarizing agents, paint, wire, plaques, pigment, fluorescent materials, liquid-filled volumes within a canister of predetermined shape, gas-filled volumes within a canister of predetermined shape, solid-filled volumes within a canister of predetermined shape and any combination thereof.

It is another object to disclose the device working in the method disclosed above, the method comprising an additional step of selecting the predetermined shape of the canister from a group consisting of a fixed cross-section with sides perpendicular to the cross-section, a fixed cross-section with sides non-perpendicular to the cross-section, a varying cross-section with sides perpendicular to the cross-section, a varying cross-section with sides non-perpendicular to the cross-section, and any combination thereof.

It is another object to disclose the device working in the method disclosed above, the method comprising an additional step of selecting the shape of the cross-section from a group consisting of a circle, a convex polygon with at least 2 and not more than 12 sides, a stellate polygon and any combination thereof.

In yet another embodiment of the canister, the tissue-containing canister is jacketed for temperature control. Temperature control can be used either to maintain the tissue at a desired temperature or to cause it to follow a desired temperature profile, or it can be used in conjunction with a thermal camera to determine differences in heat absorption by different portions of the tissue, thereby improving detection of cancerous tissue.

In some embodiments, the system comprises: an MRI imaging system adapted to image only portions of the tissue specimen proximate to the surface of the tissue specimen; a jacketed canister of predetermined shape to contain the tissue specimen, the jacketed canister adapted to induce the tissue to attain the predetermined shape; and a thermal camera to image the tissue specimen wherein the thermal camera image and the MRI image are fusible to provide a near real-time image or real time image of the surface-proximate tissue of the at least one tissue specimen.

In the embodiments disclosed above, the jacketed canister is adapted to regulate the temperature of at least a portion of the tissue specimen.

It is another object to disclose a device for MRI imaging the near surface of at least one tissue specimen excised from a body, the device working in a method of providing the system for MRI imaging surface-proximate tissue of at least one tissue specimen as disclosed above; containing the tissue specimen within the jacketed canister, thereby inducing the tissue to attain the shape of the canister; acquiring at least one MRI image of the tissue specimen; acquiring at least one thermal image of the tissue specimen; and fusing the at least one MRI image and the at least one thermal image thereby providing a near real-time image or real time image of the surface-proximate tissue of the tissue specimen.

It is another object to disclose the device working as described above, the method comprising an additional step of adapting the jacketed canister to regulate the temperature of at least a portion of the tissue specimen.

In yet another embodiment, the jacketed tissue-containing canister is used in conjunction with the hyperpolarization methods disclosed above. In embodiments with a jacketed canister and hyperpolarization of the tissue specimen, the jacket can contain water or other hyperpolarizable hyperpolarization of the water induces hyperpolarization of the tissue specimen, as disclosed above.

In some embodiments, the system comprises: an MRI imaging system adapted to image only portions of the tissue specimen proximate to the surface of the tissue specimen; hyperpolarizing agent; and a jacketed canister to contain the tissue specimen, the jacket adapted to contain hyperpolarizing agent, wherein the jacketed canister is adapted to induce hyperpolarization of the tissue specimen without contact between the hyperpolarizing agent and the tissue specimen.

It is another object to disclose a device for MRI imaging the near surface of at least one tissue specimen excised from a body, the device working in a method of providing a system for MRI imaging surface-proximate tissue of at least one tissue specimen as disclosed above; providing the hyperpolarizing agent; containing the tissue specimen within the jacketed canister; containing the hyperpolarizing agent within the jacket of the jacketed canister, thereby inducing hyperpolarization of at least one region of the tissue specimen without contact between the hyperpolarizing agent and the tissue specimen; and imaging the tissue specimen.

In other embodiments, the canister contains water, in Which the tissue specimen is immersed. In some of these embodiments, the water is hyperpolarized and hyperpolarization of the tissue specimen is induced by contact with the hyperpolarized water. Hyperpolarization can also be induced by absorption of the hyperpolarized water by the near-surface tissue, thereby preferentially hyperpolarizing the near surface tissue and preferentially increasing its visibility.

In some embodiments, the system comprises: an MRI imaging system adapted to image only portions of the tissue specimen proximate to the surface of the tissue specimen; hyperpolarizing agent; and a canister to contain the tissue specimen, the canister adapted to contain hyperpolarizing agent, the tissue specimen immersible in the hyperpolarizing agent, wherein the hyperpolarizing agent is adapted to induce hyperpolarization of the tissue specimen.

In some embodiments, the hyperpolarizing agent is selected from at least one of a group consisting of water, a solution containing ¹³C, and another hyperpolarizable liquid.

It is another object to disclose a device for MRI imaging the near surface of at least one tissue specimen excised from a body, the device working in a method of providing a system for MRI imaging surface-proximate tissue of at least one tissue specimen as disclosed above; providing hyperpolarizing agent; containing the tissue specimen within the canister; containing the hyperpolarizing agent within the canister, thereby immersing the tissue specimen in the hyperpolarizing agent and inducing hyperpolarization of at least one region of the tissue specimen; and imaging the tissue specimen.

It is another object to disclose the device working in the method discussed above, the method comprising an additional step of selecting the hyperpolarizing agent from at least one of water, a solution containing ¹³C, and another hyperpolarizable liquid.

In some embodiments, the canister is large enough that the tissue specimen can be placed within it without change of shape. In these embodiments, the canister is at least partly filled with liquid, preferably water, and the sample is immersed in the liquid. In some of these embodiments, the water is hyperpolarized, thereby preferentially hyperpolarizing the surface and near-surface tissue in the tissue specimen and improving the visibility of the margins of the tissue specimen.

In some embodiments, the fluid in which the tissue specimen is immersed contains at least one contrast agent, as described hereinabove.

In some embodiments, the system comprises: an MRI imaging system adapted to image only portions of a tissue specimen proximate to the surface of the tissue specimen; a fluid adapted to at least partially support the tissue specimen; and a canister to contain the tissue specimen, the tissue specimen containable within the canister, the canister adapted to contain the fluid wherein the tissue specimen is immersible in the fluid and further wherein the canister is adapted such that it contains the tissue specimen while retaining substantially unaffected the tissue specimen's shape.

It is another object to disclose a device for MRI imaging the near surface of at least one tissue specimen excised from a body, the device working in a method of providing the system disclosed above; providing the fluid adapted to at least partially support the tissue specimen; containing the fluid within the canister; immersing the tissue specimen in the fluid within the canister; and imaging the tissue specimen while retaining substantially unaffected the tissue specimen's shape.

In yet other embodiments, the system comprises an MRI imaging system adapted to image only surface-proximate portions of a tissue specimen, and the tissue specimen is either immersed in a pretreatment fluid or a contrast agent applied to the tissue specimen before imaging in order to increase over untreated tissue the signal from at least some portion of the surface-proximate tissue of the tissue specimen.

The pretreatment fluid can be a hyperpolarization fluid, a contrast agent and any combination thereof.

In these embodiments, the tissue specimen can be imaged by any of the means described hereinabove. During imaging, it can be immersed in fluid, supported by fluid or “dry” (not immersed in or supported by fluid). Use of a pretreatment fluid can be combined with a contrast-enhancement means applied during imaging, such as a contrast agent or hyperpolarizing agent in conjunction with the fluid in which the specimen is floating or by which it is supported, as described herein.

It is another object to disclose a device for MRI imaging the near surface of at least one tissue specimen, working in a method of providing the system disclosed above; providing at least one of a pretreatment fluid and a contrast enhancement means; at least one of immersing the tissue specimen in pretreatment fluid or applying contrast enhancement means to the surface-proximate tissue; and imaging the tissue specimen, thereby increasing signal from at least a portion of the surface-proximate tissue of the tissue specimen.

It is another object to disclose the device working in the method disclosed above, the method comprising an additional step of selecting at least one of the pretreatment fluid and the contrast enhancement means from a group consisting of hyperpolarizing fluid, a contrast agent and any combination thereof.

In some embodiments, more than one imaging modality is used; modalities can include, but are not limited to, X-ray computed tomography (CT), magnetic resonance imaging (MRI), positron emission tomography (PET), single-photon emission computed tomography (SPECT), fluorescence and phosphorescence microscopy (FPM), CCD imaging and any combination thereof.

In some embodiments of the present invention MRI images are acquired simultaneously with at least one heterogeneous CCD image, where the CCD image can be, for non-limiting example, digital subtraction angiography images, high resolution cardiography images, low dose fluoroscopy images, digital radioagraphy images, or fluorescence images. The CCD arrays can be sensitive to, for non-limiting example, X-radiation, ultraviolet radiation visible light, and infrared radiation.

In some embodiments, the non-MRI imaging device is selected from a group consisting of NMR, CT, X-ray, ultrasound device, fluorescence device, thermographic device, other thermal imaging device, IR imaging device, and any combination thereof.

In an example, a combination of MRI and radiography can be used to combine anatomical context and functional information, such as the anatomical delineation of the boundaries of a tumor (using, e.g., MRI) with the functional definition of aggressive cancer cells at the perimeter and necrotic cells at the core of the tumor (using, e.g. fluorescence images).

In some embodiments, MRI is combined with another imaging system, as described above, and further combined with a means of enhancing the sensitivity of the tissue specimen to at least one of the imaging systems. Sensitivity enhancing techniques include, but are not limited to, hyperpolarization, MRI contrast agents, fluorescence contrast agents, functionalized paramagnetic particles, and any combination thereof.

In some embodiments, the MRI device adapted to generate at least one image of surface-proximate tissue of a tissue specimen is combined with at least one photon detector to generate at least one optical image of the surface-proximate tissue of the tissue specimen and an image processor adapted to superimpose the at least one MRI image and the at least one optical image of the surface-proximate tissue of the tissue specimen, in order to generate, using any method known in the art, a rendered 3D image of the surface-proximate tissue of the tissue specimen.

The at least one photon detector is selected from a group consisting of a CCD array, a camera, a photoconductive detector array, a photovoltaic detector array, a quantum dot array, a superconducting single-photon detector array, a photovoltaic cell array, a phototube array, and any combination thereof.

It is another object to disclose a device for generating a rendered image of surface-proximate tissue of a tissue specimen excised from a body, the device working in a method of providing the MRI imaging system for generating the rendered image of the surface-proximate tissue of the tissue specimen as disclosed above; acquiring at least one MRI image of the surface-proximate tissue; acquiring at least one photon detector image of the surface-proximate tissue; and superimposing the MRI image and the photon detector image of the surface-proximate tissue of the tissue specimen, thereby generating a rendered MRI image of the surface-proximate tissue of the tissue specimen.

It is another object to disclose the device working in the method disclosed above, the method comprising an additional step of selecting at least one photon detector from a group consisting of a CCD array, a camera, a photoconductive detector array, a photovoltaic detector array, a quantum dot array, a superconducting single-photon detector array, a photovoltaic cell array, a phototube array, and any combination thereof.

In some embodiments, the MRI device adapted to generate at least one image of surface-proximate tissue of a tissue specimen is combined with at least one optical imaging system to generate at least one optical image of the surface-proximate tissue of the tissue specimen; and an image processor, wherein the image processor is adapted to superimpose the MRI image and the optical image of the surface-proximate tissue of the tissue specimen using any method known in the art, thereby generating a rendered 3D image of the surface-proximate tissue of the tissue specimen.

It is another object to disclose a device for generating a rendered image of surface-proximate tissue of a tissue specimen excised from a body, the device working in a method of providing the MRI imaging system for generating a rendered image of surface-proximate tissue of the tissue specimen excised from the body, as disclosed above; acquiring at least one MRI image of the surface-proximate tissue; acquiring at least one optical image of the surface-proximate tissue; and superimposing the MRI image and the optical image of the surface-proximate tissue of the tissue specimen, thereby generating a rendered 3D image of the surface-proximate tissue of the tissue specimen.

In some embodiments, the system comprises at least one MRI device adapted to image surface-proximate tissue of a tissue specimen; at least one optical imaging system to generate at least one optical image of the surface-proximate tissue of the tissue specimen; a hyperpolarizing means or a contrast enhancement means to increase contrast in at least one of the images of the tissue specimen; and an image processor wherein the image processor is adapted to superimpose the MRI image and the optical image of the surface-proximate tissue of the tissue specimen, thereby generating a rendered 3D image of the surface-proximate tissue of the tissue specimen.

In the embodiments disclosed above, the hyperpolarizing means is selected from at least one of a group consisting of hyperpolarizing the tissue specimen before excision of the tissue specimen, hyperpolarizing the tissue specimen by immersion in a fluid hyperpolarizing agent, and hyperpolarizing the tissue specimen by inducing hyperpolarization via proximity to a hyperpolarizing agent without contact between the hyperpolarizing agent and the tissue specimen.

It is another object to disclose a device for generating a rendered image of surface-proximate tissue of a tissue specimen excised from a body, the device working in a method of providing an MRI imaging system for generating a rendered image of surface-proximate tissue of the tissue specimen excised from the body as disclosed above; acquiring at least one MRI image of the surface-proximate tissue; acquiring at least one optical image of the surface-proximate tissue; and superimposing the MRI image and the optical image of the surface-proximate tissue of the tissue specimen, thereby generating a rendered 3D image of the surface-proximate tissue of the tissue specimen.

It is another object to disclose the device working in the method disclosed above, the method comprising an additional step of selecting the hyperpolarizing means from at least one of a group consisting of hyperpolarizing the tissue specimen before excision of the tissue specimen, hyperpolarizing the tissue specimen after excision by immersion in a fluid hyperpolarizing agent, and hyperpolarizing the tissue specimen after excision by inducing hyperpolarization via proximity to a hyperpolarizing agent without contact between the hyperpolarizing agent and the tissue specimen.

In some embodiments, the system comprises at least one MRI device adapted to image surface-proximate tissue; at least one optical imaging system to generate at least one optical image of the surface-proximate tissue; a maneuverable sensing unit comprising at least one of an RF transmitter coil and an RF receiver coil; and an image processor wherein the image processor is adapted to superimpose the MRI image and the optical image of surface-proximate tissue of the tissue specimen, thereby generating a rendered 3D image of the surface-proximate tissue of the tissue specimen and further wherein the sensing unit is adapted to be maneuvered such that the volume of interest of the MRI remains a constant distance from the surface of the tissue specimen.

The optical imaging system disclosed above can be selected from, for example, a CT imaging system, a PET imaging system, an ultrasound imaging system, an infrared imaging system, a fluorescence imaging system, a visible light imaging system, a UV imaging system and any combination thereof.

It is another object to disclose a device for generating a rendered image of surface-proximate tissue of a tissue specimen excised from a body, the device working in a method of providing an MRI imaging system for generating a rendered image of surface-proximate tissue of a tissue specimen as disclosed above; maneuvering the maneuverable sensing unit, thereby maintaining the volume of interest of the MRI at a constant distance from the surface of the tissue specimen; acquiring at least one MRI image of substantially all of the surface-proximate tissue; acquiring at least one optical image of substantially all of the surface-proximate tissue; and superimposing the MRI image and the optical image of substantially all of the surface-proximate tissue.

It is another object to disclose the device working in the method disclosed above, the method comprising an additional step of selecting the optical imaging system from a group consisting of a CT imaging system, a PET imaging system, an ultrasound imaging system, an infrared imaging system, a fluorescence imaging system, a visible light imaging system, and a UV imaging system.

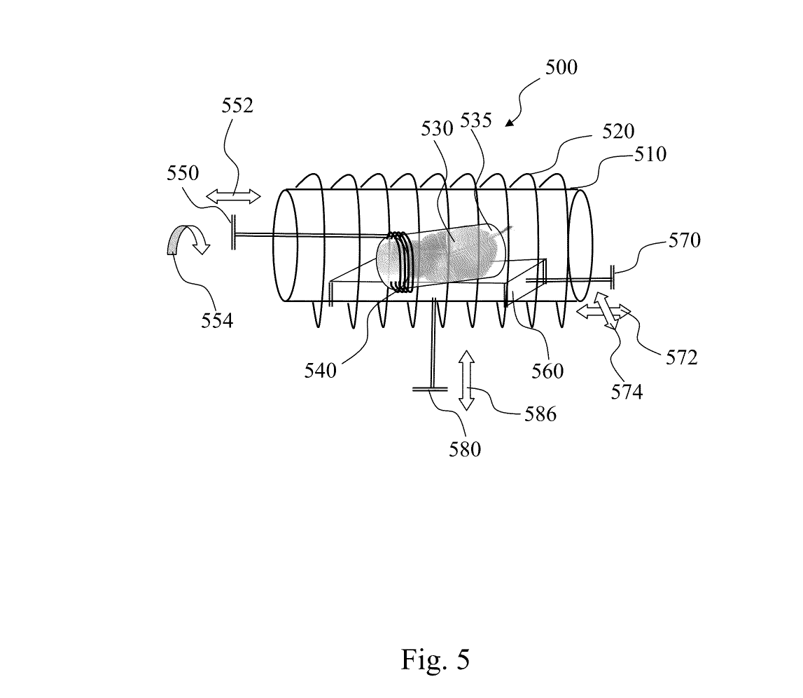

In other embodiments, the RF transmitter coil, RF receiver coil, or both can be moved to keep the volume of interest of the MRI a constant distance from the surface of the tissue. An example of an embodiment wherein both the RF transmitter coil and the RF receiver coil are movable is shown in FIG. 5, which presents a schematic drawing (side view) of an embodiment of the present device 500 comprising a movable RF transmitter coil assembly and a movable the RF receiver coil assembly. A static magnetic field is created by a magnet (not shown) external to MRI chamber 510. The magnet may be a superconducting magnet or a permanent magnet of any appropriate geometrical design. Also not shown in FIG. 5 are the gradient coils that produce the appropriate gradient magnetic fields. The design and construction of such magnets and coils is well-known in the art. A transmitter coil 520, located external to MRI chamber 510, provides RF pulses to excite magnetic nuclei within the static magnetic field according to principles well-known in the art. The tissue specimen 530, shown contained within a containment means 535 such as a canister, mortar and cradle or other containment such as is disclosed herein or known in the art, is positioned within chamber 510 such that the volume of interest is located within the static magnetic field and within the volume enclosed by transmitter coil 520. In the embodiment shown, the tissue specimen 530, within its containment, lies on a support 570. It is yet in the scope of the invention wherein (i) both coils 520 and 540 are within the internal portion of housing 510, or (ii) wherein, as shown, coil 520 located externally to the housing and coil 540 located internally, within the housing.

Receiver coil 540 substantially encircles the tissue specimen 530. Receiver coil 540 is positioned so it is a close as possible to the volume of interest. The receiver coil may be any type of RF coil, e.g. a solenoid, a Helmholtz coil, or a surface coil (loop). The inner coil does not have to be homogeneous. In the embodiment shown in FIG. 5, there is a single receiver coil; in alternative embodiments, a plurality of independent coils is present. Receiver coil 540 is attached to mechanical translation device 550.

In preferred embodiments, the maneuvering controller comprises a mechanical translation device adapted to move the receiver coil to any predetermined position along the axis (see arrow 552) defined by the static magnetic field and a mechanical rotation device to rotate the receiver coil around the axis (see arrow 554). The mechanical translation device can use any appropriate means known in the art for moving the receiver coil that is also adapted for fixing its position to within X mm (e.g. via a stepper motor); where X is in a range between about 0.1 mm and about 50 ram; between about 5 mm and about 500 mm, between about 50 mm and 1.5 m etc.

In preferred embodiments, the maneuvering controller comprises at least one further mechanical device (not shown) that can move at least one of the tissue specimen, the transmitter coil or the receiver coil so as to keep the volume of interest within the near surface of the tissue specimen. This further at least one mechanical device performs translations and/or rotations, thereby enabling the system to image substantially the entire near-surface of the tissue specimen.

In all embodiments, the translation and rotation devices of the maneuvering controller are under the control of a processor in communication with the MRI, such that feedback control can be used to provide accurate positioning of the specimen with respect to the volume of interest of the MRI.

In some embodiments, proper positioning is ensured by maneuvering the specimen only.

In other embodiments, proper positioning is ensured by maneuvering a member of a group consisting of the transmitter coil, the receiver coil, a static field magnet and any combination thereof is maneuvered, while the specimen, once placed within the MRI, is not moved relative to the surface on which it sits or by which it is held.

In yet other embodiments, both the specimen and a member of a group consisting of the transmitter coil, the receiver coil, a static field magnet and any combination thereof is maneuvered.

In the embodiment shown in FIG. 5, translation devices 570 and 580 are able to translate the tissue specimen in three mutually perpendicular directions (see arrows 572, 574, 586). In other embodiments, a combination of translation and rotation is used; if the tissue specimen has been induced into a regular shape, rotation alone can be used. For each portion of the surface-proximate region to be imaged, once the portion of the specimen is properly positioned relative to the volume of interest of the MRI, imaging can proceed according to any appropriate pulse/detection scheme.

In some embodiments, the tissue specimen is contained by a cradle and mortar; preferably neither is flat. Feedback control is used to shape the surfaces of the cradle and mortar so that they follow the contours of the tissue specimen and hold the tissue specimen gently and firmly. The MRI and, preferably, any other imaging modalities are designed so that the regions of interest of the various modalities are a fixed distance from the surface of the cradle and mortar, thereby ensuring that the regions of interest of the various modalities are a fixed distance from the surface of the tissue specimen. Note that this fixed distance can be zero, for examining the surface of the specimen.

In some embodiments, the system comprises: an MRI imaging system adapted to image only portions of a tissue specimen proximate to the surface of the tissue specimen; a cradle and mortar to contain the tissue specimen, the cradle and mortar adapted to be reshapeable; and a processing system adapted to control reshaping at least one of the cradle and mortar such that the interior surface of at least one of the cradle and mortar has the same shape as the exterior surface of the tissue specimen, with feedback control being used to control the shape of the interior surface of the cradle and mortar.

It is another object to disclose a device for MRI imaging the surface-proximate tissue of a tissue specimen excised from a body, the device working in a method of providing the system for MRI imaging the near surface of at least one tissue specimen excised from a body as disclosed above; placing the tissue specimen within the cradle and mortar; reshaping at least a portion of at least one of the cradle and mortar under feedback control such that the interior surface of at least one of the cradle and mortar has the same shape as the exterior surface of the tissue specimen; and imaging the surface-proximate tissue.

In some embodiments, the tissue specimen is gently stretched over a bed, preferably a convex bed, in order to gently flatten the tissue specimen such that the surface of the specimen follows the contours of the bed, thereby ensuring that the maximum surface area of the tissue is accessible to the imaging device or devices and inducing a substantially-constant thickness to the tissue specimen. The flattening process can be assisted by suction through the bed by, for example, having holes in the bed or making the bed of a mesh.

In some embodiments, the system comprises: an MRI imaging system adapted to image only portions of a tissue specimen proximate to the surface of the tissue specimen; a bed with a surface, the surface preferably convex, over which the tissue specimen is stretched; and a vacuum system adapted to gently induce the tissue specimen to releasably adhere to the surface wherein the stretching induces a substantially-constant thickness to the tissue specimen.

It is another object to disclose a device for MRI imaging the surface-proximate tissue of a tissue specimen excised from a body, the device working in a method of providing the system for MRI imaging the surface-proximate tissue of the tissue specimen excised from the body as disclosed above; gently stretching the tissue specimen over the bed; gently applying vacuum to the tissue specimen, thereby releasably adhering the tissue specimen to the bed; and imaging the surface-proximate tissue, thereby imaging a tissue specimen of substantially-constant thickness.

In some embodiments, time-varying MRI is carried out on the tissue specimen. In some variants of these embodiments, the tissue is treated with a contrast enhancement means, as discussed hereinabove, before excision, and the progress of the treatment is followed after excision. Examples of time-varying MRI are, but are not limited to: (i) Decay of hyperpolarization in the treated tissue, with cancerous tissue showing different patterns of decay of hyperpolarization than normal tissue. (ii) Decay of other contrast agents, with cancerous tissue showing different patterns of decay in contrast than normal tissue. (iii) Decay of fluorescence from fluorescent contrast agents, for systems in which MRI is combined with another imaging modality. (iv) Cooling rate of the tissue specimen, for systems in which MRI is combined with a thermal camera. (v) Differential perfusion of a contrast agent, wherein the location of the contrast agent is tracked over time.

In some embodiments, the system comprises: an MRI imaging system adapted to image only portions of a tissue specimen proximate to the surface of the tissue specimen, the MRI system adapted to acquire time-varying MRI images, wherein the tissue specimen is treated with a contrast-enhancement means before excision, and the time-varying MRI images are acquired after excision.

In any of the embodiments disclosed above, the contrast enhancement means is selected from a group consisting of a contrast agent, a hyperpolarizing agent, and any combination thereof.

In any of the embodiments disclosed above, the hyperpolarizing agent is selected from a group consisting of water, other hyperpolarizable liquids, ¹²⁹Xe, ³He, anesthetic gas, oxygen, an injectable solution containing ¹³C and any combination thereof.

It is another object to disclose a device for MRI imaging the surface-proximate tissue of a tissue specimen excised from a body, the device working in a method of providing an MRI imaging system adapted to image only portions of the tissue specimen proximate to the surface of the tissue specimen, the MRI system adapted to acquire time-varying MRI images; providing a contrast-enhancement means; treating the tissue specimen with the contrast-enhancement means in-vivo, before excision; excising the tissue specimen from the body; and acquiring at least one time-resolved MRI image of the surface-proximate tissue of a tissue specimen, thereby acquiring at least one contrast-enhanced time-resolved image of the tissue specimen.

It is another object to disclose the device working in the methods disclosed above, the methods comprising an additional step of selecting the contrast enhancement means from at least one of a group consisting of a contrast agent, a hyperpolarizing agent and any combination thereof.

It is another object to disclose the device working in the methods disclosed above, the methods comprising an additional step of selecting the hyperpolarizing agent from a group consisting of water, other hyperpolarizable liquids, ¹²⁹Xe, ³He, anesthetic gas, oxygen, an injectable solution containing ¹³C and any combination thereof.

It is another object to disclose the device working in the methods disclosed above, the methods comprising an additional step of selecting the contrast agent from at least one of a group consisting of functional paramagnetic particles (FPP), superparamagnetic iron platinum particles, Gadolinium(III)-containing MRI contrast agents, iron oxide contrast agents, Mn-based nanoparticles, manganese ions (Mn2+), SPIO, USPIO, barium sulfate, air, clay, Perflubron, peptides linked to high payload MRI contrast agents, antibodies linked to high payload MRI contrast agents, small ligands linked to high payload MRI contrast agents, small protein domains linked to high payload MRI contrast agents, peptides linked to MRI contrast agents with high relaxivities, antibodies linked to MRI contrast agents with high relaxivities, small ligands linked to MRI contrast agents with high relaxivities, small protein domains linked to MRI contrast agents with high relaxivities, ³He, ⁷Li, ¹³C, ¹⁹F, ¹⁷O, ²³Na, ³¹P and ¹²⁹Xe.

In some embodiments, the magnetic resonance imaging device comprises a packed array of MRIs where the packed array is a stack comprising a plurality of i MRI imaging devices of substantially no fringing magnetic fields, where the i MRI devices are arranged in an x by y by z close-packed array, where i=x*y*z. The shape of at least a portion of the stack is preferably polygonal, circular and any combination thereof.

In embodiments with packed-array MRI imaging devices, the MRI imaging devices in the packed array can be adapted to image different portions of the tissue specimen, or can have different resolutions, different contrasts or different signal-to-noise ratios and any combination of these. The images from the different MRI imaging devices can be rendered or fused to form a single image of increased resolution, contrast and/or signal to noise ratio, thereby increasing the detectability of cancerous tissue in the nominally clear margin.

In embodiments with packed-array MRI imaging devices, the tissue specimen to be imaged is placed in a canister, either closely-fitting or adapted so that the tissue specimen retains its shape. The canister is maneuvered such that each of the MRI imaging devices images substantially all of the near-surface tissue of the tissue specimen. In preferred variants of these embodiments, the maneuvering system comprises a pneumatic delivery system adapted to deliver the canister, in turn, to each of the MRI imaging devices while holding the tissue in a known orientation such that the images from the MRI imaging devices are fusible and such that each location in the resulting fused image has an unambiguous, one-to-one identification with a location in the tissue specimen and an unambiguous one-to-one identification with the location in the body which was adjacent, before excision, to the location in the tissue specimen.

In some embodiments, the system comprises: at least one packed array of MRI/NMR devices of substantially no fringing magnetic fields, adapted to analyze at least one of adjacent tissue specimens and adjacent portions of at least one tissue specimen and comprising a pneumatic delivery system adapted to deliver at least one of adjacent tissue specimens and adjacent portions of at least one tissue specimen to stages of the packed array, wherein the adjacent MRI/NMR devices differ in at least one of a group consisting of resolution, contrast and signal-to-noise ratio.

It is another object to disclose a device for MRI imaging the surface-proximate tissue of at least one tissue specimen excised from a body, the device working in a method of providing at least one packed array of MRI/NMR devices as disclosed above; placing at least one tissue specimen in the pneumatic delivery system; operating the pneumatic delivery system, thereby sequentially delivering at least one tissue specimen to each of the MRI/NMR devices of substantially no fringing magnetic fields; and, for each MRI/NMR device of substantially no fringing magnetic fields, imaging the surface-proximate tissue of the at least one tissue specimen, wherein the adjacent MRI/NMR devices differ in at least one of a group consisting of resolution, contrast and signal-to-noise ratio.

1. A system for MRI imaging the near surface of at least one tissue specimen comprising:
a. MRI comprising at least two static magnetic field magnets, at least one RF magnetic field magnet and at least one RF receiver coil, said MRI adapted to image only portions of said tissue specimen proximate to the surface of said tissue specimen; and
b. a maneuvering controller comprising a processing system, said processing system configured to enable sequential imaging of substantially all of said surface-proximate tissue by controlling maneuvering of at least one member of a group consisting of said static magnetic field magnets, said RF magnetic field magnets, said RF receiver coils, at least one said tissue specimen and any combination thereof such that the volume of interest of said MRI is substantially within said surface-proximate tissue;
wherein said volume of interest of said MRI is held substantially within said surface-proximate tissue by means of at least one of the following:
(a) said processing system is configured to enable circumnavigation of said tissue specimen by at least one of a group consisting of said static magnetic field magnets, said RF magnetic field magnets, said circumnavigation being around a vertical axis through approximately the center of said tissue specimen, said circumnavigation adapted to retain the volume of interest of said MRI within said surface-proximate tissue;
(b) at least one member of a group consisting of said RF magnetic field magnets, said RF receiver coils and any combination thereof is disposed about said tissue specimen in a horizontal planar configuration adapted to at least partially surround said tissue specimen, one direction of said maneuvering being parallel to a vertical axis through approximately the center of said tissue specimen;
(c) said MRI comprises at least one packed array of MRI/NMR devices of substantially no fringing magnetic fields, adapted to analyze at least one of adjacent tissue specimens and adjacent portions of said at least one tissue specimen and further comprising a pneumatic delivery system adapted to deliver said at least one of adjacent tissue specimens and adjacent portions of said at least one tissue specimen to stages of said packed array, wherein said adjacent MRI/NMR devices differ in at least one of a group consisting of resolution, contrast and signal-to-noise ratio;
(d) said processing system is configured to maneuver said specimen in at least two directions; and
(e) any combination thereof.

2. The system of claim 1, wherein said system is configured to acquire time-varying MRI images.

3. The system of claim 1, wherein at least one of the following is held true:
(a) said static magnetic field magnets are low-field magnets adapted to create high contrast images such that images of cancerous tissue appear to be a different intensity from images of non-cancerous tissue; and
(b) said system additionally comprises a contrast enhancer adapted to increase over untreated tissue at least one of a group selected from (i) the signal from at least some portion of said surface-proximate tissue of said tissue specimen, and (ii) the difference between at least one response to MRI of cancerous tissue and the same at least one response to MRI of normal tissue;
said contrast enhancer selected from a group consisting of a hyperpolarizing agent, a contrast agent and any combination thereof;
said contrast enhancer employed in a manner selected from a group consisting of (i) said contrast enhancer comprises a pretreatment fluid, said tissue specimen immersible in said pretreatment fluid; (ii) said contrast enhancer is adapted to be applied to said surface-proximate tissue and any combination thereof;
said tissue treated with said contrast enhancer in a manner selected from a group consisting of: in-vivo, such that said tissue specimen is treated with said contrast enhancer before excision, ex-vivo, such that said tissue specimen is treated with said contrast enhancer after excision and any combination thereof;
said in-vivo treatment selected from a group consisting of: at least one hyperpolarizing agent adapted to be introduced into said body; at least one hyperpolarization agent adapted to contact said body, said hyperpolarization agent adapted to induce hyperpolarization of at least a portion of said body via said contact; at least one hyperpolarization agent adapted to be placed in proximity to but not in contact with said body, said hyperpolarization agent adapted to induce hyperpolarization of at least a portion of said body via said proximity; at least one contrast agent adapted to be introduced into said body and any combination thereof;
said ex-vivo treatment selected from a group consisting of: at least one hyperpolarizing agent adapted to be introduced into said tissue specimen; at least one hyperpolarization agent adapted to contact said tissue specimen, said hyperpolarization agent adapted to induce hyperpolarization of at least a portion of said tissue specimen via said contact; at least one hyperpolarization agent adapted to be placed in proximity to but not in contact with said tissue specimen, said hyperpolarization agents adapted to induce hyperpolarization of at least a portion of said tissue specimen via said proximity; at least one contrast agent adapted to contact said tissue specimen, and any combination thereof;
contact between said excised tissue and contrast enhancement material is selected from a group consisting of: immersion of said excised tissue specimen in contrast enhancement fluid, injection of contrast enhancement material into said tissue specimen, coating of contrast enhancement material on said excised tissue specimen, and placement of contrast enhancement material in close proximity to said tissue specimen.

4. The system of claim 3, wherein said hyperpolarizing agent is selected from a group consisting of water, other hyperpolarizable liquids, ¹²⁹Xe, ³He, anesthetic gas, oxygen, an injectable solution containing ¹³C and any combination thereof.

5. The system of claim 3, wherein said contrast agent is selected from at least one of a group consisting of functional paramagnetic particles (FPP), superparamagnetic iron platinum particles, Gadolinium(III)-containing MRI contrast agents, iron oxide contrast agents, Mn-based nanoparticles, manganese ions (Mn²⁺), SPIO, barium sulfate, air, clay, Perflubron, peptides linked to high payload MRI contrast agents, antibodies linked to high payload MRI contrast agents, small ligands linked to high payload MRI contrast agents, small protein domains linked to high payload MRI contrast agents, peptides linked to MRI contrast agents with high relaxivities, antibodies linked to MRI contrast agents with high relaxivities, small ligands linked to MRI contrast agents with high relaxivities, small protein domains linked to MRI contrast agents with high relaxivities, ³He, ⁷Li, ¹³C, ¹⁹F, ¹⁷O, ²³Na, ³¹P and ¹²⁹Xe.

6. The system of claim 1, additionally comprising containment means for said tissue specimen;
said containment means selected from a group consisting of: a canister of predetermined shape to contain said tissue specimen, said canister adapted to induce said tissue specimen into said predetermined shape; a canister adapted to contain said tissue specimen while retaining substantially unaffected said tissue specimen's shape, said canister either containing only gas or at least partially filled with a liquid, said liquid at least partially supporting said tissue specimen; a cradle and mortar adapted to contain said tissue specimen, said cradle and said mortar reshapeable under feedback control such that the interior surface of at least one of said cradle and said mortar has substantially the same shape as the exterior surface of said tissue specimen; a bed with a surface, said surface preferably convex, over which said tissue specimen is stretched and a vacuum system adapted to gently induce said tissue specimen to releasably adhere to said surface such that said stretching induces a substantially-constant thickness to said tissue specimen; a recess in the walls of said MRI of predetermined shape, said recess adapted to contain said tissue specimen, said recess adapted to reshape said tissue specimen such that the shape of the surface of said tissue specimen is substantially the same as said predetermined shape of said recess such that nothing intervenes between said tissue specimen and said MRI; and a recess in a magnet of said MRI of predetermined shape, said recess adapted to contain said tissue specimen, said recess adapted to reshape said tissue specimen such that the shape of the surface of said tissue specimen is substantially the same as said predetermined shape of said recess such that nothing intervenes between said tissue specimen and said MRI;
the shape of said canister selected from a group consisting of a fixed cross-section with sides perpendicular to the cross-section, a fixed cross-section with sides non-perpendicular to the cross-section, a varying cross-section with sides perpendicular to the cross-section, a varying cross-section with sides non-perpendicular to the cross-section, and any combination thereof, said cross-section selected from a group consisting of a circle, a regular convex polygon with at least 2 and not more than 12 sides, an irregular polygon, a stellate polygon and any combination thereof, said varying cross-section changing in at least one manner selected from a group consisting of changing in cross-sectional size, changing in cross-sectional shape and any combination thereof.

7. The system of claim 6, wherein said containment means additionally comprises a jacket adapted to perform at least one function selected from a group selected from: regulate the temperature of at least a portion of said tissue specimen, and induce hyperpolarization of said tissue specimen without contact between said hyperpolarizing agent and said tissue specimen.

8. The system of claim 1, additionally comprising one or more indicia, said indicia adapted to unambiguously identify at least one region of said near surface of said tissue specimen, said unambiguous identification of said at least one region of said near surface adapted to ensure an unambiguous one-to-one identification between at least one location in said image, said at least one location of said near surface and at least one location within said body, said location within said body adjacent, before excision, to said region of said near surface; at least one of said indicia selected from a group consisting of MRI transparent indicia, MRI opaque indicia, hyperpolarizing indicia and any combination thereof.

9. The system of claim 8, wherein at least one of the following is held true:
(a) said indicia are selected from at least one of a group consisting of hyperpolarizing agents, paint, wire, pigment, plaques, and fluorescent materials;
(b) the location of said indicia is selected from a group consisting of: said containment means comprises said indicia; said tissue specimen comprises said indicia, said indicia being applied to said tissue specimen before the start of imaging and any combination thereof;
(c) at least one of said indicia is selected from a group consisting of: hyperpolarizing agents, paint, wire, plaques, pigment, fluorescent materials, liquid-filled volumes of predetermined shape, gas-filled volumes of predetermined shape, solid-filled volumes within said canister and any combination thereof.

10. The system of claim 1, additionally comprising at least one second imaging means selected from a group consisting of:
(a) a thermal camera to thermally image said tissue specimen;
(b) an optical imaging system to generate at least one optical image of said surface-proximate tissue of said tissue specimen, said optical imaging system selected from a group consisting of a CCD array, a camera, a photoconductive detector array, a photovoltaic detector array, a quantum dot array, a superconducting single-photon detector array, a photovoltaic cell array, a phototube array, a CT imaging system, an infrared imaging system, a fluorescence imaging system, a visible light imaging system, a UV imaging system and any combination thereof;
(c) a PET imaging system to generate a PET image of said surface-proximate tissue of said tissue specimen;
(d) an ultrasound imaging system, to generate an ultrasound image of said surface-proximate tissue of said tissue specimen;
and any combination thereof;
the image generated by said second imaging means and said MRI image fusible, thereby generating a rendered 3D image of said surface-proximate tissue of said tissue specimen.

11. A method of MRI imaging the near surface of at least one tissue specimen, comprising steps of:
a. providing an MRI system for imaging said surface-proximate tissue of said at least one tissue specimen, said MRI system comprising:
i. an MRI comprising at least two static magnetic field magnets, at least one RE magnetic field magnets and at least one RF receiver coils, said MRI adapted to image only portions of said tissue specimen proximate to the surface of said tissue specimen; and
ii. a maneuvering controller comprising a processing system, said processing system configured to enable sequential imaging of substantially all of said surface-proximate tissue by controlling maneuvering of at least one member of a group consisting of said static magnetic field magnets, said RF magnetic field magnets, said RF receiver coils, at least one said tissue specimen and any combination thereof such that the volume of interest of said MRI is substantially within said surface-proximate tissue; and
b. maneuvering at least one of said group consisting of said static magnetic field magnets, said RF magnetic field magnets, said RF receiver coils, at least one said tissue specimen and any combination thereof,
thereby holding said volume of interest of said MRI substantially within said surface-proximate tissue by means of at least one of the following:
(a) at least one member of said group consisting of static magnetic field magnets, RF magnetic field magnets, RF receiver coils and any combination thereof circumnavigating said tissue specimen around a vertical axis through approximately the center of said tissue specimen, said circumnavigation adapted such that said surface-proximate tissue remains within said volume of interest of the MRI;
(b) disposing at least one member of a group consisting of said RF magnetic field magnets, said RF receiver coils and any combination thereof about said tissue specimen in a horizontal planar configuration adapted to at least partially surround said tissue specimen, and maneuvering said at least one member of a group consisting of said RF magnetic field magnets, said RF receiver coils and any combination thereof in at least the direction parallel to a vertical axis through approximately the center of said tissue specimen, such that the volume of interest of said MRI is retained within said surface-proximate tissue;
(c) comprising said MRI of at least one packed array of MRI/NMR devices of substantially no fringing magnetic fields, thereby analyzing at least one of adjacent tissue specimens and adjacent portions of said at least one tissue specimen, said system further comprising a pneumatic delivery system adapted to deliver said at least one of adjacent tissue specimens and adjacent portions of said at least one tissue specimen to stages of said packed array, wherein said adjacent MRI/NMR devices differ in at least one of a group consisting of resolution, contrast and signal-to-noise ratio;
(a) configuring said processing system to maneuver said specimen in at least two directions; and
(e) any combination thereof.

12. The method of claim 11, additionally comprising steps of adapting said system to acquire time-varying MRI images.

13. The method of claim 11, additionally comprising at least one of the following steps:
(a) providing said static magnetic field magnets as low-field magnets adapted to create high contrast images, such that images of cancerous tissue appear to be a different intensity from images of non-cancerous tissue; and
(b) providing a contrast enhancer, said contrast enhancer increasing over untreated tissue at least one of a group selected from (i) the signal from at least some portion of said surface-proximate tissue of said tissue specimen, and (ii) the difference between at least one response to MRI of cancerous tissue and the same at least one response to MRI of normal tissue;
selecting said contrast enhancer from a group consisting of a hyperpolarizing agent, a contrast agent and any combination thereof;
employing said contrast enhancer in a manner selected from a group consisting of (i) comprising said contrast enhancer of a pretreatment fluid and immersing said tissue specimen in said pretreatment fluid; (ii) applying said contrast enhancer to said surface-proximate tissue and any combination thereof;
treating said tissue with said contrast enhancer in a manner selected from a group consisting of: in-vivo, thereby treating said tissue specimen with said contrast enhancer before excision; ex-vivo, thereby treating said tissue specimen with said contrast enhancer after excision and any combination thereof;
selecting said in-vivo treatment from a group consisting of: introducing at least one hyperpolarizing agent into said body; contacting at least one hyperpolarization agent with said body and inducing hyperpolarization of at least a portion of said body via said contact; placing at least one hyperpolarization agent proximity to but not in contact with said body and inducing hyperpolarization of at least a portion of said body via said proximity; introducing at least one contrast agent into said body and any combination thereof;
selecting said ex-vivo treatment from a group consisting of: introducing at least one hyperpolarizing agent into said tissue specimen; contacting said tissue specimen with at least one hyperpolarization agent and thereby inducing hyperpolarization of at least a portion of said tissue specimen via said contact; placing at least one hyperpolarization agent in proximity to but not in contact with said tissue specimen and thereby inducing hyperpolarization of at least a portion of said tissue specimen via said proximity; contacting said tissue specimen and at least one contrast agent, and any combination thereof;
(c) selecting said contact between said excised tissue and contrast enhancement material from a group consisting of: immersing said excised tissue specimen in contrast enhancement fluid, injecting contrast enhancement material into said tissue specimen, coating contrast enhancement material on said excised tissue specimen, and placing contrast enhancement material in close proximity to said tissue specimen.

14. The method of claim 13, additionally comprising steps of selecting said hyperpolarizing agent from a group consisting of water, other hyperpolarizable liquids, ¹²⁹Xe, ³He, anesthetic gas, oxygen, an injectable solution containing ¹³C and any combination thereof.

15. The method of claim 13, additionally comprising steps of selecting said contrast agent from at least one of a group consisting of functional paramagnetic particles (FPP), superparamagnetic iron platinum particles, Gadolinium(III)-containing MRI contrast agents, iron oxide contrast agents, Mn-based nanoparticies, manganese ions (Mn²⁺), SPIO, barium sulfate, air, clay, Perflubron, peptides linked to high payload MRI contrast agents, antibodies linked to high payload MRI contrast agents, small ligands linked to high payload MRI contrast agents, small protein domains linked to high payload MRI contrast agents, peptides linked to MRI contrast agents with high relaxivities, antibodies linked to MRI contrast agents with high relaxivities, small ligands linked to MRI contrast agents with high relaxivities, small protein domains linked to MRI contrast agents with high relaxivities, ³He, ⁷Li, ¹³C, ¹⁹F, ¹⁷O, ²³Na, ³¹P and ¹²⁹Xe.

16. The method of claim 11, additionally comprising steps of:
a. providing containment means for said tissue specimen;
b. selecting said containment means from a group consisting of: a canister of predetermined shape to contain said tissue specimen, said canister adapted to induce said tissue specimen into said predetermined shape; a canister adapted to contain said tissue specimen while retaining substantially unaffected said tissue specimen's shape, said canister either containing only gas or at least partially filled with a liquid, said liquid at least partially supporting said tissue specimen; a cradle and mortar adapted to contain said tissue specimen, said cradle and said mortar reshapeable under feedback control such that the interior surface of at least one of said cradle and said mortar has substantially the same shape as the exterior surface of said tissue specimen; a bed with a surface, said surface preferably convex, over which said tissue specimen is stretched and a vacuum system adapted to gently induce said tissue specimen to releasably adhere to said surface such that said stretching induces a substantially-constant thickness to said tissue specimen; a recess in the walls of said MRI of predetermined shape, said recess adapted to contain said tissue specimen, said recess adapted to reshape said tissue specimen such that the shape of the surface of said tissue specimen is substantially the same as said predetermined shape of said recess such that nothing intervenes between said tissue specimen and said MRI; and a recess in a magnet of said MRI of predetermined shape, said recess adapted to contain said tissue specimen, said recess adapted to reshape said tissue specimen such that the shape of the surface of said tissue specimen is substantially the same as said predetermined shape of said recess such that nothing intervenes between said tissue specimen and said MRI; and
c. selecting the shape of said canister is from a group consisting of a fixed cross-section with sides perpendicular to the cross-section a fixed cross-section with sides non-perpendicular to the cross-section, a varying cross-section with sides perpendicular to the cross-section, a varying cross-section with sides non-perpendicular to the cross-section, and any combination thereof, said cross-section selected from a group consisting of a circle, a regular convex polygon with at least 2 and not more than 12 sides, an irregular polygon, a stellate polygon and any combination thereof, said varying cross-section changing in at least one manner selected from a group consisting of changing in cross-sectional size, changing in cross-sectional shape and any combination thereof.

17. The method of claim 11, additionally comprising steps of providing a jacket for said canister, said jacket performing at least one function selected from a group selected from: regulate the temperature of at least a portion of said tissue specimen, and induce hyperpolarization of said tissue specimen without contact between said hyperpolarizing agent and said tissue specimen.

18. The method of claim 11, additionally comprising steps of: providing one or more indicia; unambiguously identifying at least one region of said near surface of said tissue specimen by means of said indicia, said unambiguous identification of said at least one region of said near surface ensuring an unambiguous one-to-one identification between at least one location in said image, said at least one location of said near surface and at least one location within said body, said location within said body adjacent, before excision, to said region of said near surface; selecting at least one of said indicia from a group consisting of MRI transparent indicia, MRI opaque indicia, hyperpolarizing indicia and any combination thereof.

19. The method of claim 11, additionally comprising at least one of the following steps:
(a) selecting said indicia from at least one of a group consisting of hyperpolarizing agents, paint, wire, pigment, plaques, and fluorescent materials;
(b) selecting the location of said indicia from a group consisting of: said containment means comprise said indicia; said tissue specimen comprises said indicia, said indicia applied to said tissue specimen before the start of imaging and any combination thereof; and
(c) selecting at least one of said indicia from a group consisting of hyperpolarizing agents, paint, wire, plaques, pigment, fluorescent materials, liquid-filled volumes of predetermined shape, gas-filled volumes of predetermined shape, solid-filled volumes within said canister and any combination thereof.

20. The method of claim 11, additionally comprising steps of providing at least one second imaging means and selecting said at least one second imaging means from a group consisting of:
(a) a thermal camera to thermally image said tissue specimen;
(b) an optical imaging system to generate at least one optical image of said surface-proximate tissue of said tissue specimen, said optical imaging system selected from a group consisting of a CCD array, a camera, a photoconductive detector array, a photovoltaic detector array, a quantum dot may, a superconducting single-photon detector array, a photovoltaic cell array, a phototube array, a CT imaging system, an infrared imaging system, a fluorescence imaging system, a visible light imaging system, a UV imaging system and any combination thereof;
(c) a PET imaging system to generate a PET image of said surface-proximate tissue of said tissue specimen;
(d) an ultrasound imaging system, to generate an ultrasound image of said surface-proximate tissue of said tissue specimen;
and any combination thereof;
the image generated by said second imaging means and said MRI image fusible, thereby generating a rendered 3D image of said surface-proximate tissue of said tissue specimen.
